(19) United States
(12) Patent Application Publication
(10) Pub. No.: US 2006/0258132 A1
(43) Pub. Date: Nov. 16, 2006

(54) Templated cluster assembled wires

(76) Inventors: Simon Anthony Brown, Christchurch (NZ); James Gordon Partridge, Christchurch (NZ)

Correspondence Address: DANN, DORFMAN, HERRELL & SKILLMAN, 1601 MARKET STREET, SUITE 2400, PHILADELPHIA, PA, 19103-2307, US

(21) Appl. No.: 10/544,948

(22) PCT Filed: Jan. 29, 2004
(86) PCT No.: PCT/NZ04/00012

§ 371 Date: May 15, 2006

(30) Foreign Application Priority Data
Feb. 7, 2003 (NZ) 524059

(51) Int. Cl. H01L 21/44

(52) U.S. Cl. 438/610

(57) ABSTRACT

Methods of preparing electrically conducting wire-like structures for use in for example electronic devices, and the devices formed by such methods are described. One example of such a method of preparing said structures relies on the assembly of conducting particles using surface templates to assist in the formation of a wire-like structure. Said structures may be prepared on the nanoscale, but also up to the micronscale.

### FIELD OF THE INVENTION

The present invention relates to methods of preparing electrically conducting wire-like structures for use in electronic devices and the devices formed by such methods. More particularly but not exclusively the invention relates to a method of preparing such structures on the nanoscale, but also up to the micron scale, by the assembly of conducting particles using surface templates to assist in the formation of a wire-like structure.

### BACKGROUND TO THE INVENTION

Nanotechnology has been identified as a key technology for the 21st century. This technology is centred on an ability to fabricate electronic, optical and opto-electronic devices on the scale of a few billionths of a metre. In the future, such devices will underpin new computing and communications technologies and will be incorporated in a vast array of consumer goods.

There are many advantages of fabricating nanoscale devices. In the simplest case, such devices are much smaller than the current commercial devices (such as the transistors used in integrated circuits) and so provide opportunities for increased packing densities, lower power consumption and higher speeds. In addition, such small devices can have fundamentally different properties to those fabricated on a larger scale, and this then provides an opportunity for completely new device applications.

One of the challenges in this field is to develop nanostructured devices that will take advantage of the laws of quantum physics. Electrical devices with dimensions of ˜100 nm that operate on quantum principles (such as single electron transistors and quantum wires) have generally been proven at only low temperatures (<−100° C.). The challenge now is to translate these same device concepts into structures with dimensions of only a few nanometres, since the full range of quantum effects and novel device functionalities could then be available at room temperature. Indeed, as discussed below, some prototype nanoscale devices have been fabricated that demonstrate such quantum effects at relatively high temperatures. However, as is also discussed below, there remain many challenges to overcome before such devices find commercial applications.

In general, there are two distinct approaches to fabricating nanoscale devices:
‘top-down’, and
‘bottom up’.

In the ‘top-down’ approach, devices are created by a combination of lithography and etching. The resolution limits are determined by, for example, the wavelength of light used in the lithography process: lithography is a highly developed and reliable technology with high throughput but the current state of the art (using UV radiation) can achieve devices with dimensions ˜10 nm only at great expense. Other lithography techniques (e.g. electron beam lithography) provide (in principle) higher resolution but with a much slower throughput.

The ‘bottom-up’ approach proposes the assembly of devices from nanoscale building blocks, thus immediately achieving nanoscale resolution, but the approach usually suffers from a range of other problems, including the difficulty, expense, and long time periods that can be required to assemble the building blocks. A key question is whether or not the top-down and bottom-up approaches can be combined to fabricate devices which take the best features of both approaches while circumventing the problems inherent to each approach.

An example of a prior art development which attempts to use this combination of approaches is the highly successful fabrication of transistors from carbon nanotubes [1]. Contacts are fabricated using lithography, and a nanoscale building block (in the form of a nanometre thick carbon nanotube) is used to provide the conducting path between the contacts. These transistors have been shown [2,3] to exhibit quantum transport effects and to have transistor characteristics comparable to those of Si-MOSFITs used in integrated circuits, and are therefore in principle usable in commercial applications. However, the difficulty in isolating and manipulating single nanotubes to form reproducible devices may prevent widespread commercial usage. Hence the development of new techniques for the formation of nanoscale wire structures between electrically conducting contacts is an important technological problem.

General Background to Nanowire Formation Methods

One simple approach to the formation of nanoscale wires is to stretch a larger wire until it is close to the breaking point with a diameter of just a few atoms (See e.g. Ref [4] and refs therein; similar effects can be achieved using scanning tunnelling microscopes). At this point the break junction can exhibit quantised conductance. This technique, while interesting, is not well suited to device formation since generally the technique is difficult to control, only a single wire can be fabricated at any time, and since multi-terminal devices cannot be easily achieved.

Another approach is to use a combination of lithographic and electrochemical techniques to achieve narrow wires and/or contacts with nanometre scale spacing [5]. Electrochemical deposition of Cu allows the observation of quantised conduction and a chemical sensor has been developed from these nanowires [6]. While these devices are promising it remains to be demonstrated that they can be fabricated sufficiently controllably or reproducibly for commercial applications, or that multi-terminal or other electronic devices can be fabricated using this method.

Reference [7] describes an electric-field assisted assembly technique used to position individual nanowires suspended in a dielectric medium between two electrodes defined lithographically on a silicon dioxide substrate. The forces that induce alignment are the result of nanowire polarisation in an applied alternating electric field. The Au nanowires (diameter 350 nm) are formed using electrodeposition into a nanoporous alumina membrane and are then suspended in isopropyl alcohol. This method provides high quality contacted nanowires of prescribed length and cross-sectional area in an effective and well controlled manner. It does however require dual electrodeposition and wire-substrate application processes, and pre-fabrication of the wires By contrast, momentum driven cluster nanowires are formed directly between the device contacts that they finally connect, and our ability to sense the formation of the wire and the self contacting inherent to our process are important advantages.

In reference [8] ultrafine nanowires are synthesized by injecting a liquid melt into nanoporous alumina membranes. A large area (10×15 mm) of parallel wires with diameters as small as 13 nm, lengths of 30-50 μm and packing density as high as 7.1×10¹⁰ cm⁻² has been fabricated. The optical absorption spectra of the nanowire arrays indicate that these bismuth nanowires undergo a semimetal-to-semiconductor transition due to two-dimensional confinement effects. This method is similar to others involving the filling of nanoporous alumina with a chosen nanowire material. Vacuum injection represents a refinement of the technique and allows much smaller wire diameters to be attained than are possible using electrodeposition. This method provides uncontacted nanowires but allows prescription of the length and affords very high yield.

Nanowires have been extruded spontaneously (at room temperature) at a rate of a few micrometers per second from the surfaces of freshly grown composite thin films consisting of bismuth and chrome-nitride. [9] The high compressive stress in these composite thin films is the driving force responsible for nanowire formation. This nanowire production method is simple to perform but does not result in contacted nanowires and will not produce nanowires of uniform width or length.

Nanojunctions have been formed in copper wires which are electrodeposited between contacts (separation 100 nm) on silicon. [10] The contact-contact conductance was monitored until a desired value was reached and the plating potential was controlled using a feedback circuit. Reversing the potential allowed thinning of an established copper connection down to nanoscale width and height. This method is based on controlled electrodeposition onto substrates with preformed contacts. Wires are formed with necks that are a few nanometres in width and display quantum confinement properties. The requirement for monitoring and reverse plating capability for each contact that is formed probably means that this technique could not be scaled for high yield production of these nanojunctions. The method is also unsuitable for producing true nanowires.

Devices Achieved Through Deposition of Atomic Clusters

The proposal [11] that structures on the scale of a few nanometres could be formed using atomic clusters, which are nanoscale particles formed by simple evaporation techniques (see for example [12,13]), has already caught the imagination of a few groups internationally [14]. It has been shown that clusters can diffuse across a substrate [15] and then line up at certain surface features, thus generating cluster chain structures [16,17,18], although in these cases the chains are usually incomplete (have gaps) and such chains have so far not been connected to electrical contacts on non-conducting substrates. This approach is promising because the width of the wire is controlled by the size of the clusters, but the problem of positioning the clusters to form real devices on useful substrates has yet to be solved.

Devices formed using atomic clusters have been reported in Refs [8,19,20]: a network of clusters is formed by an ion beam deposition method [15] between two contacts which are defined using electron beam lithography. In this work clusters were formed by deposition of atomic vapour and not by deposition of preformed nanoparticles onto the substrate. The devices exhibit the Coulomb Blockade effect at T=77K [8] but apparently quantum effects are not visible at room temperature. In this work only clusters of AuPd and Au have been employed and, importantly, in these devices conduction through the cluster network was by tunnelling. No method was described which lead to the controllable formation of a conducting path, and only two terminal devices were described, and hence a device similar to the nanotube transistors described above was not formed.

A number of devices (see for example [21,22,23]) have been fabricated which incorporate single (or a very limited number) of nanoscale particles. These devices are potentially very powerful but, equally, are most likely to be subject to difficulties associated with the expense and long time periods that can be required to assemble the building blocks. Device to device reproducibility, and difficulty of positioning of the nanoparticles may be additional problems. Furthermore the preferred embodiment of these devices requires that the nanoparticle be isolated from the contacts by tunnel barriers whose properties are critical to the device performance, since tunnelling currents depend exponentially on the barrier thickness. In some cases the use of a scanning tunnelling microscope leads to a slow and not scalable fabrication process. Recent progress in this area has resulted in the first single electron transistors fabricated with a single atom as the island onto which tunnelling occurs [23]. While this is a significant achievement, and an element of self assembly in the fabrication is attractive, such devices are still far from commercial production and the methods used may not be viable for large scale production.

Wet chemical methods (see for example [21]) have also been shown to be useful with respect to fabrication of nanoscale devices and offer some promise as a method of overcoming the difficulties in positioning nanoparticles. While these techniques may still be important in the future, the limitations include the limited range of types of nanoparticles that can be formed using these techniques, the difficulty in coding specific sites to attract nanoparticles, and there are so far unanswered questions regarding their suitability for scaling.

Finally we mention that several experiments (see for example [24,25,26,27,28,29]) have been performed on percolation in films of metal nanoparticles. Typically nanoparticles are deposited between electrical contacts and a clear onset of conduction can be observed at the percolation threshold. Only recently has percolation in films of nanoparticles where the films have nanoscale overall dimensions (i.e. where the contact separation is small) been studied and proposed to be useful as a method of forming nanoscale devices[30]. The key to this proposal is a recognition that the formation of wire-like structures at or near the percolation threshold can be controlled by the geometry of the electrical contacts.

Templated Nanowire Assembly Methods

Large arrays of Au nanowires down to 50 nm in width have been fabricated on V-grooved InP substrates[31]. Holographic laser interference exposure of photoresist and anisotropic etching was used to pattern the surface of the InP (001) substrates into V-shaped grooves with 200 nm period (sawtooth). The patterned substrates were then covered with a thin Au film which is structured into nanowires using a well controlled wet etching process. The cluster assembled nanowires discussed here utilise a similar substrate topology and both approaches offer the ability to form nanowires around existing device contacts. The wet-etching process described above is isotropic and would require constant monitoring. Care would need to be taken in order to avoid accelerated undercut effects often witnessed when etching around patterned photoresist This constitutes a processing stage that could lower yield and prove labour-intensive.

AuFe nanowires ranging from 50-120 nm in width have been prepared by oblique coevaporation of Au and Fe onto V-groove (sawtooth) patterned InP substrates[32]. The magnetic properties of these nanowires were investigated via magnetization and magnetoresistance measurements between 4.2 and 300K This process again offers a similar substrate topology to that utilised in cluster assembly in V-grooved silicon channels and is an inexpensive and potentially high yield means to produce contacted planar nanowires but because it uses atomic deposition it again does not use the advantages of cluster deposition.

Cu clusters have been formed in chains from Cu atoms deposited onto a Si (111) surface patterned with (2-5 μm width) lines of photoresist[33]. In addition to a thin Cu layer on the exposed Si surface, large (˜150 nm) clusters nucleate at the boundary between the Si and the resist strips. These clusters remain after dissolution of the photoresist. The main disadvantage with this method is the lack of isolation offered by the prepatterned substrates. In addition to the aggregated clusters at the resist step edge, significant films exist over the uncovered silicon surface. The nanowires are thus connected in pairs by a thin film of unknown resistance. It is unclear whether the size of the clusters can be controlled, and the usual limitations of lithography apply to the resolution with which the width of the wire can be determined.

CaF₁ and CaF₂ clusters were assembled along step edges on silicon (111) and used as a mask for subsequent deposition of Fe nanowires via photolysis of ferrocene molecules[34]. This technique involves extensive pre-treatment of the silicon surface which precludes the use of preformed contacts and may prevent this method from scaling to high yield applications.

In reference [35] Au clusters were deposited from solution onto a silicon dioxide surface prepatterned with photoresist. After removal of the photoresist, preferential cluster accumulation was observed along the edges of the resist structures. (As ref. 33) The main disadvantage with the method of Ref. 33 is the lack of isolation offered by the prepatterned substrates but in Ref [35] this has been overcome by treatment of the silicon dioxide substrate so that it becomes hydrophilic. Stray Au islands still form in the areas between the photoresist-edge nanowires and therefore the potential for close packing these nanowires is compromised. The reliance on standard lithography techniques for the formation of wires remains a problem.

Metallic molybdenum wires with diameters ranging from 15 nm to 1 um and lengths up to 500 um have been prepared in a two-step procedure[36,37]. Molybdenum oxide wires were electrodeposited selectively at step edges and then reduced in hydrogen gas at 500 deg C. to yield Mo. The metal nanowires were then embedded in a polystyrene film and lifted off the graphite electrode surface. Conductivity was measured and was comparable to that of bulk molybdenum. This technique was employed in [37] to produce palladium mesowire arrays for hydrogen sensing applications. Whilst this method shows great potential and a large-scale application has been demonstrated the polystyrene carrier substrate will not suit many electronic device assemblies, and the lift-off of the wires from the initial substrate is a relatively crude procedure which may have significant impact on the mortality of the wires.

Fabrication of periodic nanoscale Ag-wire arrays on vicinal CaF₂ surfaces has been achieved by using 3 nm diameter Ag clusters which are moved by means of an AFM tip until they accumulate on steps formed on an ion-beam polished CaF₂ surface. [38] This technique is extremely labour and time intensive. The speed with which nanowires can be formed is not realistic for anything other than pure science applications.

Formation of ordered assemblies from deposited gold clusters has been achieved using 2-8 nm gold nanocrystals formed on 2 nm thick carbon films. [39] Aggregation is witnessed and intact nanocrystals with a very narrow size range can be deposited as long as the impact energy is below 40 eV. The subsequent surface motion of the nanocrystals after impact results in cluster-cluster collisions, which for larger clusters (>4 nm) produces aggregations but for smaller clusters (<3.5 nm) results in complete fusion and reformation into larger aggregated clusters with approximately spherical symmetry. Aggregation is enhanced at defects in the carbon film. In reference [40] samples are produced by deposition of preformed gold clusters on a functionalised graphite surface. Surface defects are obtained using a Focused Ion Beam (FIB) nanoengraving technique. The main disadvantage of these methods for the assembly of clusters on carbon/graphite films [39, 40] is that in order for integration of nanodevices into microelectronics to be a realistic end goal, silicon (unpassivated or passivated) must be the chosen substrate material and that carbon is simply inappropriate.

### OBJECT OF THE INVENTION

It is an object of the invention to provide a method of preparing nanoscale or up to micronscale wire-like structures, and/or devices formed therefrom which overcome one or more of the abovementioned disadvantages, or which at least provide the public with a useful alternative.

### SUMMARY OF THE INVENTION

According to a first aspect of the invention there is provided a method of forming at least a single conducting chain of particles on a substrate comprising or including the steps of:
a. Modifying the substrate surface to provide a topographical feature, or identifying a topographical feature on the substrate surface;
b. preparing a plurality of particles,
c. deposition of a plurality of particles on the substrate,
d. formation of a conducting chain of particles.

Preferably there is a further step of:
i. Forming two or more contacts on the substrate surface

Which may:
precede, follow or be simultaneous with Step a. and the deposition is in the region between the contacts, and the conducting chain of particles is between the contacts, or
follow step d. and the contacts may be so located that the conducting chain of particles is between them, providing electrical conduction between them.

Preferably the modification includes formation of a step, depression or ridge in the substrate surface.

Preferably the modification comprises formation of a groove having a substantially v-shaped cross-section or inverted pyramid structure, preferably running substantially between the contacts.

Preferably the surface modification step:
involves the use of etching and takes advantage of the different etch rates of crystallographic planes in the substrate material, and/or
involves lithography.

Preferably the particles are sized between 0.5 nm and 100 microns and provide a chain of width between 0.5 nm and 100 microns.

Preferably the particles are smaller than the size of the v-groove; preferably the chain may be many particles in width.

Preferably the particles are composed of two or more atoms, which may or may not be of the same element.

More preferably the particles are nanoparticles and provide a chain of dimensions between 0.5 nm and 100 microns.

Preferably the formation of the conducting chain of particles relies upon the migration, sliding, bouncing or other movement of the particles across or on the surface of the substrate which is due, at least in part, to kinetic energy imparted to the particles prior to deposition.

Preferably there are two contacts which are separated by a distance smaller than 100 microns, more preferably the contacts are separated by a distance less than 1000 nm.

Preferably the length of the wire is defined by the spacing between the contacts, the length of the V-groove or other surface modification.

Preferably the nanoparticles may be of uniform or non-uniform size, and the average diameter of the nanoparticles is between 0.5 nm and 1,000 nm.

Preferably the nanoparticle preparation and deposition steps are via inert gas aggregation and the nanoparticles are atomic clusters made up of a plurality of atoms which may or may not be of the same element.

Preferably the substrate is an insulating or semiconductor material, more preferably the substrate is selected from silicon, silicon nitride, silicon oxide aluminium oxide, indium tin oxide, germanium, gallium arsenide or any other III-V semiconductor, quartz, or glass.

Preferably the nanoparticles are selected from bismuth, antimony, aluminium, silicon, platinum, palladium, germanium, silver, gold, copper, iron, nickel or cobalt clusters.

Preferably the contacts are formed by lithography.

Preferably the nature of the chain of particles is controlled by one or more of the following:
control of the angle of incidence of the deposition of clusters onto the substrate so as to affect the density of particles or their ability to slide, stick or bounce, in or on any part or parts of the substrate;
control of the angle of the topographical feature(s) on the substrate so as to affect the density of particles or their ability to slide, stick or bounce, in or on any part or parts of the substrate;
adjustment or control of the kinetic energy of the particles to be deposited on the substrate by control of the gas pressures and/or nozzle diameters of an inert gas aggregation source and/or associated vacuum system and/or velocity of gas from the nozzle
control of the substrate temperature,
control of the substrate surface smoothness,
control of the surface type and/or identity.

Preferably the formation of the at least a single conducting chain is either by:
i. monitoring the conduction between the contacts and ceasing deposition at or after the onset of conduction, and/or
ii. usage of a deposition rate monitor to achieve the desired wire thickness.

Preferably conduction through the chain is initiated by an applied voltage or current, either during or subsequent to the deposition of the particles.

Preferably prior to deposition, one or more of the following processes may occur:
ionisation of particles
size selection of particles
acceleration and focussing of clusters
the step of oxidising or otherwise passivating the surface of the v-groove (or other template) so as to modify the subsequent motion of the incident particles
selection of particle and substrate materials and particle's kinetic energy so as to cause the particle to bounce off a part of the substrate (for example the unmodified areas between surface modifications), thereby preventing the formation of a conducting path in that area of the substrate.
selection of size of surface modification (e.g. width of V-groove) and so as to control the thickness of the wire formed

According to a second aspect of the invention there is provided a single conducting chain of particles on a substrate prepared substantially according to the above method.

According to a third aspect of the invention there is provided a method of forming a conducting wire between two contacts on a substrate surface comprising or including the steps of:
a. forming the contacts on the substrate,
b. preparing a plurality of particles,
c. depositing a plurality of particles on the substrate at least in the region between the contacts,
d. monitoring the formation of the conducting wire by monitoring conduction between the two contacts, and ceasing deposition at or after the onset of conduction,
wherein the contacts are separated by a distance smaller than 100 microns.

Preferably the formation of the conducting chain of particles relies upon the migration, sliding, bouncing or other movement of the particles across or on the surface of the substrate which is due, at least in part, to kinetic energy imparted to the particles prior to deposition.

Preferably the formation of the conducting chain of particles relies upon the migration, sliding, bouncing or other movement of the particles across or on the surface of the substrate into or proximal to a topographical feature formed in the surface of the substrate, or into or proximal to, a pre-existing topographical feature.

Preferably the nature of the conducting wire is controlled by one or more of the following:
control of the angle of incidence of the deposition of clusters onto the substrate so as to affect the density of particles or their ability to slide, stick or bounce, in or on any part or parts of the substrate;
control of the angle of the topographical feature(s) on the substrate so as to affect the density of particles or their ability to slide, stick or bounce, in or on any part or parts of the substrate;
adjustment or control of the kinetic energy of the particles to be deposited on the substrate by control of the gas pressures and/or nozzle diameters of an inert gas aggregation source and/or associated vacuum system and/or velocity of gas from the nozzle
control of the substrate temperature,
control of the substrate surface smoothness,
control of the surface type and/or identity.

Preferably the method includes an additional step before or after step a) or b) but at least before step c) of: surface modification to provide topographical assistance to the positioning of the depositing particles in order to give rise to a conducting pathway.

Preferably the surface modification may be formation of a step, depression or ridge in the substrate surface.

Preferably the modification comprises formation of a groove having a substantially v-shaped cross-section or an inverted pyramid running substantially between the contacts.

Preferably the particles are sized between 0.5 nm and 100 microns and provide a chain of dimensions 0.5 nm and 100 microns.

Preferably the particles are composed of two or more atoms, which may or may not be of the same element.

More preferably the particles are nanoparticles and provide a chain of dimensions between 0.5 nm and 100 microns.

Preferably the nanoparticles have an average diameter between 0.5 nm and 1,000 nm, and may be of uniform or non-uniform size.

Preferably the particle preparation and deposition steps are via-inert gas aggregation and the particles are atomic clusters made up of two or more atoms, which may or may not be of the same element.

Preferably the modification is by lithography and etching.

Preferably the substrate is an insulating or semiconducting material; more preferably the substrate is selected from silicon, silicon nitride, silicon oxide, aluminium oxide, indium tin oxide, germanium, gallium arsenide or any other III-V semiconductor, quartz, glass.

Preferably the particles are selected from bismuth, antimony, aluminium, silicon, platinum, palladium, germanium, silver, gold, copper, iron, nickel or cobalt clusters.

Preferably conduction through the chain is initiated by an applied voltage or current, either during or subsequent to the deposition of the particles.

Preferably prior to deposition, one or more of the following processes may occur:
ionisation of particles
size selection of particles
acceleration and focussing of clusters
the step of oxidising or otherwise passivating the surface of the v-groove (or other template) so as to modify the subsequent motion of the incident particles
selection of particle and substrate materials and particle's kinetic energy so as to cause the particle to bounce off a part of the substrate (for example the unmodified areas between surface modifications), thereby preventing the formation of a conducting path in that area of the substrate.
selection of size of surface modification (e.g. width of V-groove) and so as to control the thickness of the wire formed.

According to a fourth aspect of the invention there is provided a conducting wire between two contacts on a substrate surface prepared substantially according to the above method.

According to a fifth aspect of the invention there is provided a method of forming a conducting wire between two contacts on a substrate surface comprising or including the steps of:
a. forming the contacts on the substrate,
b. preparation of a plurality of particles,
c. depositing a plurality of particles, on the substrate in the region between the contacts,
d. achieving a single wire running substantially between the two contacts by modifying the substrate to achieve, or taking advantage of preexisting topographical features which will cause the particles to form the wire.

Preferably the particles are sized between 0.5 nm and 100 microns and provide a chain of dimensions between 0.5 nm and 100 microns.

Preferably the particles are composed of two or more atoms, which may or may not be of the same element.

More preferably the particles are nanoparticles and provide a chain of dimensions between 0.5 nm and 100 microns.

Preferably the formation of the conducting chain of particles relies upon the migration, sliding, bouncing or other movement of the particles across or on the surface of the substrate which is due, at least in part, to kinetic energy imparted to the particles upon deposition.

Preferably the nature of the conducting wire is controlled by one or more of the following:
control of the angle of incidence of the deposition of clusters onto the substrate so as to affect the density of particles or their ability to slide, stick or bounce, in or on any part or parts of the substrate;
control of the angle of the topographical feature(s) on the substrate so as to affect the density of particles or their ability to slide, stick or bounce, in or on any part or parts of the substrate;
adjustment or control of the kinetic energy of the particles to be deposited on the substrate by control of the gas pressures and/or nozzle diameters of an inert gas aggregation source and/or associated vacuum system an/or velocity of gas from the nozzle
control of the substrate temperature,
control of the substrate surface smoothness,
control of the surface type and/or identity.

Preferably the contacts are separated by a distance smaller than 100 microns; more preferably the contacts are separated by a distance smaller than 100 nm.

Preferably the average diameter of the nanoparticles is between 0.5 nm and 1,000 nm, and may be of uniform or non-uniform size.

Preferably the nanoparticle preparation and deposition steps are via inert gas aggregation and the nanoparticles are atomic clusters made up of two or more atoms which may or may not be of the same element.

Preferably the contacts are formed by lithography.

Preferably any modification of step d is by lithography.

Preferably the substrate is an insulating or semiconducting material.

Preferably the substrate is selected from silicon, silicon nitride, silicon oxide, aluminium oxide, indium tin oxide, germanium, gallium arsenide or any other III-V semiconductor, quartz, or glass.

Preferably the nanoparticles are selected from bismuth, antimony, aluminium, silicon, platinum, palladium, germanium, silver, gold, copper, iron, nickel or cobalt clusters.

Preferably conduction through the chain is initiated by an applied voltage or current, either during or subsequent to the deposition of the particles.

Preferably prior to deposition, one or more of the following processes may occur:
ionisation of particles
size selection of particles
acceleration and focussing of clusters
the step of oxidising or otherwise passivating the surface of the v-groove (or other template) so as to modify the subsequent motion of the incident particles
selection of particle and substrate materials and particle's kinetic energy so as to cause the particle to bounce off a part of the substrate (for example the unmodified areas between surface modifications), thereby preventing the formation of a conducting path in that area of the substrate.
selection of size of surface modification (e.g. width of V-groove) and so as to control the thickness of the wire formed

According to a sixth aspect of the invention there is provided a conducting wire between two contacts on a substrate surface prepared substantially according to the above method.

According to a seventh aspect of the invention there is provided a method of fabricating a device including or requiring a conduction path between two contacts formed on a substrate, including or comprising the steps of:
A. preparing a conducting wire between two contacts on a substrate surface as described in any of the above methods.
B. incorporating the contacts and wire into the device.

Preferably the device includes two or more contacts and includes one or more of the conducting wires.

Preferably the device is a nanoscale device, and the wire(s) is (are) a nanowire(s).

Preferably conduction through the chain is initiated by an applied voltage or current, either during or subsequent to the deposition of the particles.

Preferably the step of incorporation results in any one or more of the following embodiments:
1. two primary contacts having the conducting nanowire between them, and at least a third contact on the substrate which is not electrically connected to the primary contacts thereby capable of acting as a gate or other element in a amplifying or switching device, transistor or equivalent; and/or
2. two primary contacts having the conducting nanowire between them, an overlayer or underlayer of an insulating material and at least a third contact on the distal side of the overlayer or underlayer from the primary contacts, whereby the third contact is capable of acting as a gate or other element in a switching device, transistor or equivalent; and/or
3. the contacts and/or nanowire are protected by an oxide or other non-metallic or semi-conducting film to protect it and/or enhance its properties; and/or
4. a capping layer (which may or may not be doped) is present over the surface of the substrate with contacts and nanowire, which may or may not be the film of 3.
5. the nanoparticles being annealed on the surface of the substrate;
6. the position of the nanoparticles are controlled by a resist or other organic compound or an oxide or other insulating layer which is applied to the substrate and then processed using lithography and/or etching to define a region or regions where nanoparticles may take part in electrical conduction between the contacts and another region or regions where the nanoparticles will be insulated from the conducting network.

Preferably the device is a transistor or other switching device, a film deposition control device, a magnetic field sensor, a chemical sensor, a light emitting or detecting device, or a temperature sensor.

Preferably the device is a deposition sensor and the nanoparticles are entirely metallic such that the onset of ohmic conduction is used to monitor the film thickness.

Preferably the device is a deposition sensor and the nanoparticles are coated in ligands or an insulating layer such that the onset of tunnelling conduction is used to monitor the film thickness.

Preferably prior to deposition, one or more of the following processes may occur:
ionisation of particles
size selection of particles
acceleration and focussing of clusters
the step of oxidising or otherwise passivating the surface of the v-groove (or other template) so as to modify the subsequent motion of the incident particles
selection of particle and substrate materials and particle's kinetic energy so as to cause the particle to bounce off a part of the substrate (for example the unmodified areas between surface modifications), thereby preventing the formation of a conducting path in that area of the substrate.
selection of size of surface modification (e.g. width of V-groove) and so as to control the thickness of the wire formed

According to an eighth aspect of the invention there is provided a device including or requiring a conduction path between two contacts formed on a substrate prepared substantially according to the above method.

According to a ninth aspect of the invention there is provided a nano-to micro-scale device including or requiring a conduction path between two contacts formed on a substrate including or comprising:
i) At least two contacts on the substrate,
ii) plurality of particles forming a conducting chain or path of particles between the contacts,
   wherein the particles are deposited upon the surface from an inert gas aggregation source, and wherein formation of the conducting chain of particles relies upon the migration, sliding, bouncing or other movement of the particles across or on the surface of the substrate. More preferably this sliding, bouncing or other movement is due, at least in part, to kinetic energy imparted to the particles prior to deposition.

Preferably the nature of the conducting chain or path of particles is controlled by one or more of the following:
control of the angle of incidence of the deposition of clusters onto the substrate so as to affect the density of particles or their ability to slide, stick or bounce, in or on any part or parts of the substrate;
control of the angle of the topographical feature(s) on the substrate so as to affect the density of particles or their ability to slide, stick or bounce, in or on any part or parts of the substrate;
adjustment or control of the kinetic energy of the particles to be deposited on the substrate by control of the gas pressures and/or nozzle diameters of an inert gas aggregation source and/or associated vacuum system an/or velocity of gas from the nozzle
control of the substrate temperature,
control of the substrate surface smoothness,
control of the surface type and/or identity.

Preferably the device is a nanoscale device, and the particles are nanoparticles.

Preferably there are two contacts which are separated by a distance smaller than 10 microns.

Preferably the contacts are separated by a distance less than 1000 nm.

Preferably conduction through the chain is initiated by an applied voltage or current, either during or subsequent to the deposition of the particles

Preferably the nanoparticles are composed of two or more atoms, which may or may not be of the same element.

Preferably the nanoparticles may be of uniform or non-uniform size, and the average diameter of the nanoparticles is between 0.5 nm and 1,000 nm.

Preferably the substrate is an insulating or semiconducting material.

Preferably the substrate is selected from silicon, silicon nitride, silicon oxide, aluminium oxide, indium tin oxide, germanium, gallium arsenide or any other III-V semiconductor, quartz, or glass.

Preferably the nanoparticles are selected from bismuth, antimony, aluminium, silicon, platinum, palladium, germanium, silver, gold, copper, iron, nickel or cobalt clusters.

Preferably the at least a single conduction chain has been formed either by:
i. monitoring the conduction between the contacts and ceasing deposition at or after the onset of conduction, and/or
ii. modifying the substrate surface, or taking advantage of pre-existing topographical features, which will cause the nanoparticles to form the nanowire when deposited in the region of the modification or topographical features.

Preferably prior to deposition, one or more of the following processes may occur:
ionisation of particles
size selection of particles
acceleration and focussing of clusters
the step of oxidising or otherwise passivating the surface of the v-groove (or other template) so as to modify the subsequent motion of the incident particles
selection of particle and substrate materials and particle's kinetic energy so as to cause the particle to bounce off a part of the substrate (for example the unmodified areas between surface modifications), thereby preventing the formation of a conducting path in that area of the substrate.
selection of size of surface modification (e.g. width of V-groove) and so as to control the thickness of the wire formed

According to a tenth aspect of the invention there is provided a single conducting chain of particles between a number of contacts on a substrate substantially as described herein with reference to any one or more of the figures and or examples.

According to an eleventh aspect of the invention there is provided a conducting wire between two contacts on a substrate surface substantially as described herein with reference to any one or more of the figures and or examples.

According to a twelfth aspect of the invention there is provided a method of preparing a single conducting chain of particles between a number of contacts on a substrate substantially as described herein with reference to any one or more of the figures and or examples.

According to a thirteenth aspect of the invention there is provided a method of preparing a conducting wire between two contacts on a substrate surface substantially as described herein with reference to any one or more of the figures and or examples.

Definitions

“Nanoscale” as used herein has the following meaning—having one or more dimensions in the range 0.5 to 1000 nanometres.

“Nanoparticle” as used herein has the following meaning—a particle with dimensions in the range 0.5 to 1000 nanometres, which includes atomic clusters formed by inert gas aggregation or otherwise.

“Particle” as used herein has the following meaning—a particle with dimensions in the range 0.5 nm to 100 microns, which includes atomic clusters formed by inert gas aggregation or otherwise.

“Wire” as used herein has the following meaning—a pathway formed by the assembly particles (which may range in size from 1 nm to 100 microns) which is electrically conducting substantially or entirely via ohmic conduction (as compared to tunnelling conduction, for example). It is not restricted to a single linear form but may be direct, or indirect. It may also have side branches or other structures associated with it. The particles may or may not be partially or fully coalesced, so long as they are able to conduct. The definition of wire may even include a film of particles which is homogeneous in parts but which has a limited number of critical pathways; it does not include homogeneous films of particles or homogeneous films resulting from the deposition of particles. The definition of wire includes, in the context of TeCAN devices, wires which have a diameter larger than the diameter of the clusters used to form it, and includes wires in which substantial numbers of clusters may be identified (partially coalesced or not) across the width of the wire.

“Nanowire” as used herein has the following meaning—a pathway formed by the assembly nanoparticles which is electrically conducting substantially or entirely via ohmic conduction (as compared to tunnelling conduction, for example). It is not restricted to a single linear form but may be direct, or indirect. It may also have side branches or other structures associated with it. The nanoparticles may or may not be partially or fully coalesced, so long as they are able to conduct. The definition of nanowire may even include a film of particles which is homogeneous in parts but which has a limited number of critical pathways; it does not include homogeneous films of nanoparticles or homogeneous films resulting from the deposition of nanoparticles. The definition of nanowire includes, in the context of TeCAN devices, wires which have a diameter larger than the diameter of the clusters used to form it, and includes wires in which substantial numbers of clusters may be identified (partially coalesced or not) across the width of the wire (e.g, a wire with overall dimensions of order 1000 nm which is comprised of clusters of order 20 nm).

“Contact” as used herein has the following meaning—an area on a substrate, usually but not exclusively comprising an evaporated metal layer, whose purpose is to provide an electrical connection between the nanowire or cluster deposited film and an external circuit or an other electronic device. Preferably, but not exclusively, the contacts in the devices described here are prepared using lithography, in such a way that they extend to the apexes of the V-groove or other template in order to make contact the cluster assembly at the apex.

“Atomic Cluster” or “Cluster” as used herein has the following meaning—a nanoscale aggregate of atoms formed by any gas aggregation or one of a number of other techniques [41] with diameter in the range 0.5 nm to 1000 nm, and typically comprising between 2 and 10⁷ atoms.

“Substrate” as used herein has the following meaning—an insulating or seminconducting material comprising one or more layers which is used as the structural foundation for the fabrication of the device. The substrate may be modified by the deposition of electrical contacts, by doping or by lithographic processes intended to cause the formation of surface texturing.

“Conduction” as used herein has the following meaning—electrical conduction which includes ohmic conduction but excludes tunnelling conduction. The conduction may be highly temperature dependent as might be expected for a semiconducting nanowire as well as metallic conduction.

“Chain” as used herein has the following meaning—a pathway or other structure made up of individual units which may be part of a connected network. Like a nanowire it is not restricted to a single linear form but may be direct, or indirect. It may also have side branches or other structures associated with it. The nanoparticles may or may not be partially or fully coalesced, so long as they are able to conduct. The definition of chain may even include a film of particles which is homogeneous in parts but which has a limited number of critical pathways; it does not include homogeneous films of nanoparticles or homogeneous films resulting from the deposition of nanoparticles.

“Template” A surface feature, typically created using a combination of lithography and etching, which is used to enhance the probability of formation of a wire-like structure when clusters are deposited onto the surface of the device.

“V-groove” A V-shaped trench created on the surface of a suitable substrate which acts as a template for the formation of a wire-like structure. V-groove includes other similar structures such as inverted pyramids, inverted pyramids with square bottoms, trenches with trapezoidal cross-sections. The V-groove is not necessarily symmetrical.

“Diffusion” random motion of clusters across a surface i.e. Brownian motion. Diffusion does not have any directional component e.g. due to residual momentum of an incident particle.

“Sliding” directed motion of a cluster across a surface, for example when the initial momentum or kinetic energy of a cluster causes a continuation of the motion of the cluster in that direction even after contact with the surface. This may include motion in which contact with the surface is maintained, or where the cluster leaves the surface temporarily “Bouncing”.

“Passivation” describes the modification of the substrate surface in order to change its physical or chemical properties and in particular to eliminate undesirable reactivity of the original surface, for example by coating with a polymer or growth of an oxide layer.

### BRIEF DESCRIPTION OF THE FIGURES

The invention is further described with reference to the accompanying figures:

FIG. 1. Field Emission SEM image of clusters on a flat silicon surface, between V-grooves.

FIG. 2. Sb cluster assembled wire with minimum width of less than 100 nm. Source inlet Ar flow-rate was 150 sccm.

FIG. 3. Enhanced aggregation of bismuth clusters in a silicon V-groove at high coverage. Ar flow rate 90 sccm.

FIG. 4. Comparison of cluster size and cluster aggregation in silicon V-groove and on neighbouring silicon plateau. Ar flow rate 90 sccm.

FIG. 5. Comparison of bismuth aggregated clusters wires on silicon V-grooves and silicon dioxide coated V-grooves.

FIG. 6. SEM images of Bi clusters produced using source inlet argon flow rates of (a) 30 sccm (b) 60 sccm (c) 90 sccm and (d) 180 sccm and deposited on Si (i) and SiO₂ (ii) V-grooves. At higher flow rates, cluster free regions exist at the top of the V-grooves and compact wires form at the apexes.

FIG. 7. SEM images of Sb clusters produced using source inlet argon flow rates of (a) 30 sccm (b) 60 sccm and (c) 90 sccm and deposited on Si (i) and SiO₂ (ii) V-grooves. A near complete absence of clusters is seen near the top of the Si V-grooves and on the planar Si surfaces.

FIG. 8. Sb cluster coverage at the apex of a silicon dioxide coated V-groove (a) and on the neighbouring plateaus (b) for clusters deposited with argon flow 180 sccm.

FIG. 9. Aggregated antimony cluster wires in silicon V-grooves.

FIG. 10. High deposition conditions for antimony on V-grooved silicon. (V-grooves are filled whilst plateaus have less than 10% coverage).

FIG. 11. (a) SEM image of a 3 μm wide, 150 μm long contacted Sb mesowire and (b) its associated post-formation, in-vacuum I(V) plot. The Sb clusters were deposited with a source argon flow-rate of 90 sccm. The insets to (a) are high resolution FE-SEM images of the wire and the relatively small number of clusters on the plateau.

FIG. 12: Schematic illustration of the cluster deposition process.

FIG. 13: Similar device to that in FIG. 15 but with V-grooves between contacts 1 and 3.

FIG. 14 Schematic of photodiode based on cluster chain.

FIG. 15. Schematic illustration of a three terminal device.

FIG. 16. Atomic Force Microscope (AFM) image of a V-groove etched into silicon using KOH.

FIG. 17. Schematic illustration of a cluster assembled nanowire created using an AFM image of a V-groove.

FIG. 18. Side view of a FET structure fabricated by deposition of an insulating layer on top of the cluster assembled nanowire followed by lithographic definitions of a gate contact.

FIG. 19. AFM images of the bottom of an ‘inverted pyramid’ etched into silicon using KOH.

FIG. 20 The calculated ratio of the kinetic and detachment energies as a function of cluster size for bismuth liquid drops. Ratios greater then 1 imply a high probability that an incident drop will bounce.

FIG. 21. (a) and (b) SEM images of Ag clusters produced using a source inlet argon flow rates of 180 sccm and deposited on a SiO₂ passivated V-grooved substrate. As is the case for similarly deposited Sb clusters, a near complete absence of clusters is seen near the top of the V-grooves and on the planar surfaces.

FIG. 22. SEM image of Si clusters deposited on a SiO₂ passivated V-grooved substrate. A near complete absence of clusters is seen near the top of the V-grooves and on the planar surfaces. Significant coalescence of the aggregated Si clusters at the apex of the V-groove leads to the formation of a continuous Si nanowire with extremely uniform width.

FIG. 23 Width of the low-coverage region (Δ) for Sb clusters found on the walls of 4 μm wide SiO₂ passivated Si V-grooves (o) and the coverage within this region (x) for various Ar flow-rates.

FIG. 24. Coverage on the plateaus versus coverage at the apex for Sb clusters of average diameter 40, 25 and 15 nm. The clusters shown in (a), (b) and (c) were deposited with identical Ar flow-rates and with similar velocities. Significant variation is seen in the coverage on the plateaus (<1% to >100%) whilst the V-grooves are comparably filled. This difference in cluster-sticking on the plateaus is attributed to the variation in mass and therefore kinetic energy (K.E.) of the deposited clusters. Larger clusters have higher K.E. and are more likely to be reflected from the silicon dioxide surfaces perpendicular to the cluster beam.

FIG. 25. Variation of cluster-free region with the angle of incidence for Bi clusters. (a)-(c) show a silicon dioxide passivated V-groove with wall angles of 57.2° (right-hand wall) and 52.3° (left-hand wall). (a) and (b) show the right-hand and left-hand cluster-free regions for the medium coverage case and (c) shows higher coverage and a cluster-free region only on the right-hand wall.

FIG. 26. Ratio ξ of the kinetic energy of a reflected Sb cluster to the energy of attachment to a surface calculated as a function cluster radius, R. ξ>1 indicates that the cluster should bounce. The incident cluster velocities are 500, 200, 100, 50, 20, 10 m/s (from top to bottom).

FIG. 27. Ratio ξ of the kinetic energy to the attachment to a surface energy of reflected 40 nm diameter Sb and Bi clusters calculated as a function of cluster velocity. ξ>1 indicates that the cluster should bounce.

### DETAILED DESCRIPTION OF THE INVENTION

The present invention discloses our method of fabricating wire-like structures by the assembly of conducting nanoparticles. The advantages of our technology (compared with many competing technologies) include that:
Electrically conducting nanowires can be formed using only simple and straightforward techniques, i.e. cluster deposition and relatively low resolution lithography.
The resulting nanowires can be automatically connected to electrical contacts if desired.
Electrical current can be passed along the nanowires from the moment of their formation.
No manipulation of the clusters is required to form the nanowire because the wire is “self assembled” using surface templating techniques described below.
The width of the nanowire can be controlled by the size of the cluster that is chosen.
In general, the usage of clusters in this work offers an opportunity to fabricate wires which have diameters controlled by the cluster diameter, which significantly smaller than dimensions achievable with lithographic processes, and may be significantly simpler.

While the formation of nanowires is emphasised herein the method of this invention is not limited to wires of nanoscale dimensions, but may also prove useful for the formation of larger wires up to 100 um in width.

A. Method of the Invention

The invention relies upon a number of steps and/or techniques:
1. the formation of lithographically defined patterns on a substrate intended to guide clusters in the assembly of wires (whether on the nanoscale or greater)
2. the formation of contacts on the templated substrate (this is an optional step but is present in most embodiments)
3. the formation of nanoscale particles (atomic clusters)
4. Deposition of the clusters onto the templated substrate
5. monitoring the formation of the nanowire pathway. (This is an optional step).

As mentioned previously, although much of this discussion refers to nanowires and nanoparticles, the method of the invention also includes up to the micron scale preparation of wires. Wires of this scale may well be formed by the deposition of micron scale clusters, but equally may well be formed by the deposition of many nanoscale particles which combine to give a wire-like structure on the micron scale.

1. Formation of Surface Template Structures

Electron beam lithography and photolithography are well-established techniques in the semiconductor and integrated circuit industries and currently are the preferred means of contact formation. These techniques are routinely used to form many electronic devices ranging from transistors to solid-state lasers. In our technology the standard lithography processes are used to produce surface templates intended to guide clusters in the assembly of nanowires. As will be appreciated by one skilled in the art, other techniques of the art which allow for nano-scale contact formation will be included in the scope of the invention in addition to electron beam lithography and photolithography, for example nanoimprint lithography.

Lithography, in conjunction with various etching techniques, can be used to produce surface texturing. In particular, there are various well-established procedures for the formation of V-grooves and related structures such as inverted pyramids, for example by etching silicon with KOH. The scope of the invention includes additional lithography steps designed to achieve surface patterns which assist in the formation of nanowires.

2. Formation of Contacts

In our technology the standard lithography processes are used to produce the contacts to our devices and the active component of the device is a nanowire formed by the deposited atomic clusters. As will be appreciated by one skilled in the art, other techniques of the art which allow for nano-scale contact formation will be included in the scope of the invention in addition to electron beam lithography and photolithography, for example nanoimprint lithography. It is possible that the contacts are formed after the nanowire is deposited (post-contacting). Although this is within the scope of the invention, this is not the preferred embodiment.

Finally there may also be instances where this step is omitted altogether and the product of the process is simply one or more nanowires. While usually contacts are an essential element of the devices described herein, and indeed automatic contacting to the devices is a key part of the invention, there are a number of applications in which self assembly of uncontacted nanowires may prove useful. One such example is that of a wire grid polariser, which comprises a large number of parallel uncontacted wires.

3. Formation of Atomic Clusters

This is a process whereby metal vapour is evaporated into a flowing inert gas stream which causes the condensation of the metal vapour into small particles. The particles are carried through a nozzle by the inert gas stream so that a molecular beam is formed. Particles from the beam can be deposited onto a suitable substrate. This process is known as inert gas aggregation (IGA), but clusters could equally well be formed using cluster sources of any other design (see e.g. the sources described in the review [41]).

4. Cluster Deposition

The basic design of a cluster deposition system is described in Ref 42 and the contents of which are hereby incorporated by way of reference. It consists of a cluster source and a series of differentially pumped chambers that allow ionisation, size selection, acceleration and focussing of clusters before they are finally deposited on a substrate. In fact, while such an elaborate system is desirable, it is not essential, and our first devices have been formed in relatively poor vacuums without ionisation, size selection, acceleration or focussing.

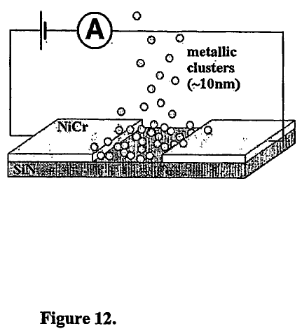

The acceleration of the clusters by the flowing inert gas stream through a series of nozzles determines the kinetic energy of the particles in the present experiments, although, as will be appreciated by one skilled in the art, there are many methods of controlling the kinetic energy of the particles, including the use of charged clusters and electrostatic or pulsed electric fields. FIG. 12 illustrates the basic deposition of clusters on to a sample with lithographically defined contacts.

5. Monitoring the Formation of the Nanowire

When used, this step generally involves the monitoring of the conduction between a pair of electrical contacts and ceasing deposition of atomic clusters upon the formation of a conducting connection between the contacts. Alternative or further embodiments may involve monitoring the formation of more than one nanowire structure where more than one nanowire may be useful.

We monitor the formation by checking for the onset of conduction between two contacts. As is discussed below this requires incorporating into our deposition system electrical feedthroughs into the deposition chamber, to allow electrical measurements to be performed on devices during deposition.

There may be some aspects of the invention where this conduction monitoring may not be required and other variables, such as time of deposition for example, may be employed to estimate or monitor formation. Such other means of generally “monitoring” the formation of the nanowire are included within the scope of the invention.

B. Resultant Technologies: Templated Cluster Assembled Nanodevices (Hereinafter TeCANs) and the Related Method

This method relies on the same technologies as PeCAN devices [30] except that in addition to cluster deposition and the fabrication of electrical contacts on an appropriate substrate the substrate is etched (or otherwise patterned) to enhance the formation of nanoparticle chains.

It is well established that small particles can diffuse when they land on a sufficiently smooth surface. The particles move or migrate until they hit a defect or another particle: for sufficiently low particle fluxes arriving at the surface, the particles aggregate at defects without significantly aggregating with each other. TeCAN is based on the concept that motion of the clusters whether it be due to diffusion, bounding, sliding, or any other kind of motion, can be arrested by a suitable defect can be engineered to achieve cluster aggregation into nanowires.

The more sophisticated TeCAN technology requires an additional stage of lithographic processing to create surface texturing between the electrical contacts. TeCAN devices could be used for all applications previously discussed for PeCAN devices[30], but the technology allows the formation of devices with much smaller overall dimensions. Therefore TeCAN devices are more appropriate to applications requiring a high density of devices, for example, transistors.

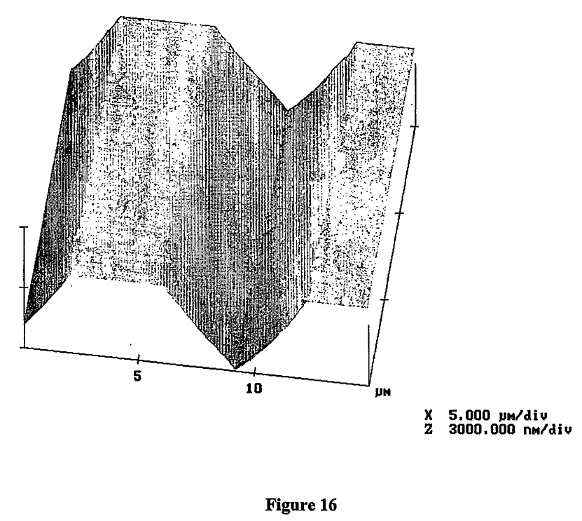

In the preferred embodiment, the invention involves using standard lithographic techniques to cause the formation of one or more V-grooves between a pair of electrical contacts (see FIGS. 16, 17, and 18). The flat sides of the V-grooves will allow migration of clusters to the apex of the V-groove where they will be localised. Hence, they will gradually aggregate to form a nanowire along the apex of the V-groove. One of the attractions of this technique is that the natural tendency of the V-groove to form an orthogonal facet at the end of the groove allows an opportunity to form wires with four contacts. This is likely to be important in a variety of applications.

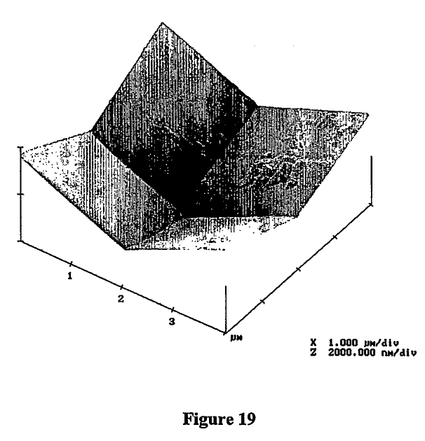

We can monitor the nanowire formation in the V-groove by measuring the onset of conduction as discussed above (see FIG. 19). Alternatively a wire can be formed and its conduction measured only after its formation.

It is to be noted that although the V-groove texturing discussed is the preferred form of the invention, other forms of surface texturing are included in the scope of the invention.

Temperature Considerations

One requirement for PeCAN technology[30] is that when clusters land on the insulating surface between the electrical contacts they do not move significantly. In contrast, TeCAN technology relies on surface migration, sliding or bouncing of the clusters for the formation of the nanowire. Temperature control of the surface could be used to change the mobility of the clusters on the surface, for example to allow clusters to migrate on surfaces on which they would otherwise be immobile. Because relatively few studies have been done on cluster migration, the variety of cluster/substrate combinations to which TeCAN technology can be applied is not yet clear. However, semiconductor systems such as gallium arsenide and silicon are known to be suitable for the formation of V-grooves, and it is expected that cluster materials which do not form strong bonds to the substrate will be most mobile. Variations in both the surface and cluster temperature could be used to change the cluster mobility, for example by changing the wetting of the surface by the cluster.

Our experimental results, discussed below, indicate that the predominant form of migration is sliding and bouncing of clusters, especially when incident at an angle which is not the normal to a V-groove facet (which is always the case for at least one of the two sides of the V-groove, since they are at an angle to each other), is important in assisting the formation of a wire-like structure at the apex of the V-groove (or other template) in the improved TeCAN methodology.

Factors Influencing the Outcome

There are a large number of factors or parameters within this work which, when altered, can influence the result of a given deposition. These factors include (but are not restricted to) the following. The ranges provided in brackets are not restrictive but merely indicative of where that parameter may typically lie. These parameters will clearly depend upon many factors in a particular case, such as the identity of the metal cluster. It may be that certain situations will require a parameter outside these ranges.
gas flow rate (1-5000 sccm)
deposition process times (1-10000 s)
crucible temperature (300-2000K)
V-groove width (10 nm-100 μm)
cluster size (0.5-1000 nm)
identity of the metal of the cluster
identity of the substrate and/or a passivation layer on the substrate
type of and/or geometry of the surface template
angle of impact/incidence (0-90°)
smoothness of surface (<100 nm r.m.s. roughness)
temperature of the substrate (<1000K)
source pressure (0.1-100 mbar)
nozzle diameters (0.1-10 mm)
size and profile of the beam spot
rate of deposition (0.001-1000 angstroms/s)
type of cluster source (inert gas or magnetron sputter types)

Given the importance of the migration of the clusters across the substrate surface in the invention and the role that the kinetic energy of the clusters plays in this migration, it is to be expected that a number of the above factors will have some impact on the energetics of the system.

C. Applications of the Invention

An important characteristic of the nanowires formed by the method of the invention is that in general they will be sensitive to many different external factors (such as light, temperature, chemicals, magnetic fields or electric fields) which in turn give rise to a number of applications. Devices of the invention may be employed in any one of a number of applications. Applications of the devices include, but are not limited to:

Transistors or Other Switching Devices.

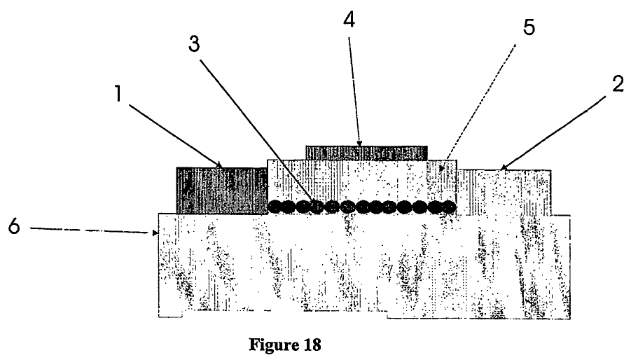

A number of the devices described below allow switching using a mode similar to that of a field effect transistor. FIG. 18 illustrates such a device.

Transistors formed from a combination of electron beam lithography and the placement of a single gated carbon nanotube (which simply acts as a nanowire) between electrical contacts have been fabricated by a number of groups (see e.g. [1]) and have been shown to perform with transconductance values close to those of the silicon MOSFET devices used in most integrated circuits. TeCAN technology can be used to form an equivalent conducting nanowire between a pair of contacts. This wire can be seen as a direct replacement for the carbon nanotube in the carbon nanotube transistor. The advantage of using TeCAN technology to form these devices is that these technologies eliminate the need to use slow and cumbersome manipulation techniques to position the nanowire. Using TeCAN technology the nanowire is automatically connected to the electrical contacts, and in the case of TeCAN technology the position of the nanowire is predetermined.

In all cases it is critical that a third (gate) contact is provided to control current flow through the nanowire. To achieve switching the use of both top gate (see FIG. 18) and bottom gate technology can be considered. However the preferred embodiment is the use of a TeCAN device with a third contact in the same plane, or close to the same plane, as the nanowire. In this case the TeCAN based transistor is very similar to that of the carbon nanotube transistor discussed above[1].

The preferred embodiment of this device is one in which semiconductor nanoparticles such as germanium clusters are guided to the apex of a V-groove (or V-grooves) etched into the substrate which may be a different semiconductor, such as silicon or Gallium Arsenide, or possibly the same semiconductor but with a thin oxide layer to insulate the nanowire from the substrate. Further preferred embodiments of this device involve metallic cluster wires such as Bismuth or Nickel nanowires.

Magnetic Field Sensors.

Magnetic Field Sensors are required for a large number of industrial applications but we focus here on their specific application as a sensor for the magnetic information stored on a high density hard disk drive, or other magnetically stored information, where suitably small magnetic field sensors must be used as readheads. The principle is that the smaller the active component in the readhead, and the more sensitive, the smaller the bits of information on the hard drive can be, and the higher the data storage density.

Magnetoresistance is usually expressed as a percentage of the resistance at zero magnetic field and MR is used as a figure of merit to define the effectiveness of the readhead. Appropriate nanowires are well established as being highly sensitive to magnetic fields, i.e., large magnetoresistances (MR) can be obtained. For example, it has recently been reported that a nickel nanowire can have a MR of over 3000 percent at room temperature. [43] This far exceeds the MR of the GMR effect readhead devices currently in commercial production.

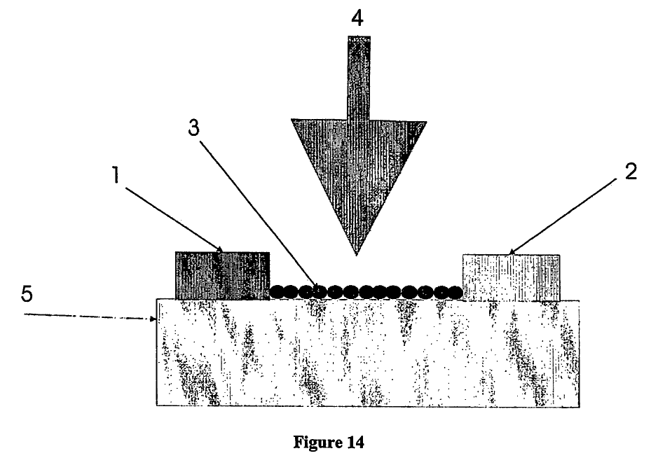

The active part of a readhead based on TeCAN technology would be a cluster assembled nanowire, for example a Nickel or Bismuth nanowire formed by cluster deposition between appropriate contacts (similar to devices shown in FIGS. 14 and 18). Note that the resolution of the readhead would be governed by the size of the nanowire and not by the overall device size (i.e. the contact size is not necessarily important) so even with PeCAN technology high sensitivity readheads might be possible. The mechanism governing the high magnetoresistances required for readheads in TeCAN devices is likely to be spin-dependant electron transport across sharp domain walls within the wire [43] or any one of a number of other effects (or combination of these effects), such as weak or strong localisation, electron focusing, and the fundamental properties of the material from which the clusters are fabricated (e.g. bismuth nanowires are reported to have large MR values).

Furthermore we note that well-defined nanowires may not be essential to the formation of a suitably sensitive readhead. Devices with more complicated cluster networks may also be useful because of the possibility of magnetic focusing of the electrons by the magnetic field from the magnetically stored information, or other magneto-resistive effects. In the case of focusing of the electrons into electrical contacts other than the source and drain and/or into deadends within the cluster network this might result in very strong modulations of the magnetoresistance (measured between source and drain) similar to those achieved in certain ballistic semiconducting devices.

Chemical Sensors.

The devices discussed in Ref. [6] demonstrate that a narrow wire can be useful for chemical sensors, and similar chemical sensitivity should be possible due to the response of the narrow wire formed in the narrowest part of devices of the invention. It is well established that very narrow wires, i.e. with nanometre diameters, whether exhibiting quantum conductance or not, can have their conductance modulated strongly by the attachment of molecules to the surface of the wire. This may result from wave function spillage or chemical modification of the surface of the wire. The strong modulation of the conductance of the wire can lead to high chemical sensitivity.

The nanowires formed in TeCAN devices, as well as larger cluster networks with a critical current path at some point in the network, may be useful for chemical sensing applications. These applications may be in industrial process control, environmental sensing, product testing, or any one of a number of other commercial environments.

The preferred embodiment of the device is one similar to that shown in FIG. 14 which uses a cluster material which is sensitive to a particular chemical. Exclusivity would be useful, i.e., it would be ideal to use a material which senses only the chemical of interest and no other chemical, but such materials are rare.

A preferred embodiment of the chemical sensing device is an array of TeCAN nanowires, each formed from a different material. In this case each of the devices acts as a separate sensor and the array of sensors is read by appropriate computer controlled software to determine the chemical composition of the gas or liquid material being sensed. The preferred embodiment of this device would use conducting polymer nanoparticles formed between metallic electrical contacts, although many other materials may equally well be used.

A further preferred embodiment of this device is a TeCAN formed nanowire which is buried in a insulating material, which is itself chemically sensitive. Chemical induced changes to the insulating capping layer will then produce changes in the conductivity of the nanowire. A further preferred embodiment of the device is the use of a insulating and inert capping layer surrounding the nanowire with a chemically sensitive layer above the nanowire, e.g., a suitable conducting polymer layer (i.e. similar to FIG. 18, but with the gate replaced by a chemically sensitive polymer layer). The conducting polymer is then affected by the introduction of the appropriate chemical; changes in the electrical properties of the conducting polymer layer are similar to the action of a gate which can then cause a change in the conduction through the nanowire. Similar devices currently in production are called CHEMFETs.

Light Emitting or Detecting Devices

The devices discussed above (and particularly devices similar to that shown schematically in FIG. 14, which illustrates two contacts 1, 2, on an insulating substrate 5, with cluster chain 3 between the contacts. Light 4 is incident upon the cluster chain 3) may exploit the optical properties of the nanoparticles to achieve a device which responds to or emits light of any specific wavelength or range of wavelengths including ultra-violet, visible or infra-red light and thereby forms a photodetector or light emitting diode, laser or other electroluminescent device.

CCD based on silicon technology are well established as the market leaders in electronic imaging. Arrays of TeCAN formed nanowires could equally well be useful as photodetectors for imaging purposes. Such arrays could find applications in digital cameras, and a range of other technologies.

The preferred embodiment of a TeCAN photodetector is a semiconductor nanowire, for example, a wire whose electrical conductance is strongly modulated by light, formed from silicon nanoparticles. In this regard semiconductor nanowires with ohmic contacts at each end may be appropriate, but it is perhaps more likely that wires connected to a pair of oppositely doped contacts may be more effective. FIG. 14 shows a schematic version of the preferred embodiment—a photodiode based on a cluster chain. The choice of the contacts (either ohmic or Schottky) will significantly influence the response of the device to light. The wavelength of light which the device responds to can be tuned by selection of the diameter of the clusters and/or cluster assembled wire. This is particularly the case for semiconductor nanoparticles where quantum confinement effects can dramatically shift the effective bandgap. Similar devices can be made to emit light. Semiconductor quantum wires built into p-n junctions (e.g. contacts 1 and 2 made to p and n type) can emit light and if built into suitable structures, lasing can be achieved

Transistor-like devices (see above) may be the most appropriate as light sensors since they are particularly suited to connection to external or other on-chip electronic circuits.

The wavelength of light which the device responds to can be tuned by selection of the diameter of the clusters and/or cluster assembled wire. This is particularly the case for semiconductor nanoparticles where quantum confinement effects can dramatically shift the effective bandgap.

Similar devices to those discussed above can be made to emit light. Semiconductor quantum wires built into p-n junctions (e.g. contacts 1 and 2 made to p and n type) can emit light and if built into suitable structures, lasing can be achieved

Temperature Sensors.

The unusual properties of the devices may include a rapid or highly reproducible variation in conductivity with temperature, which may be useful as a temperature sensor. Schematic diagrams of devices which might be useful in this regard are shown in FIGS. 14 and 18.

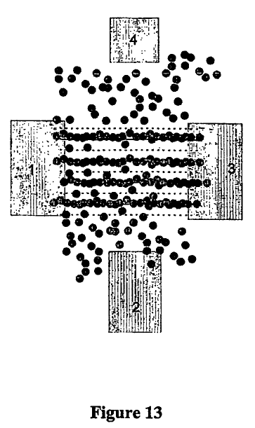

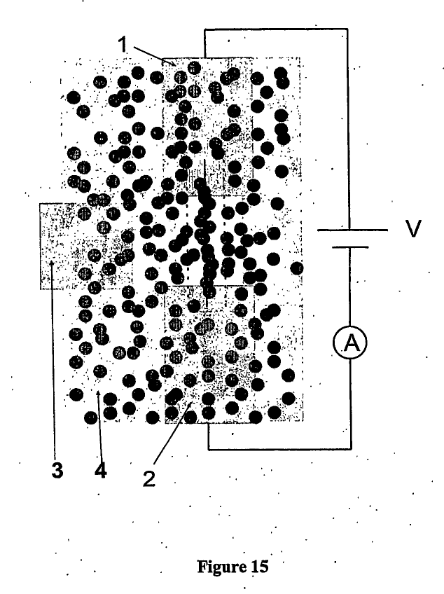

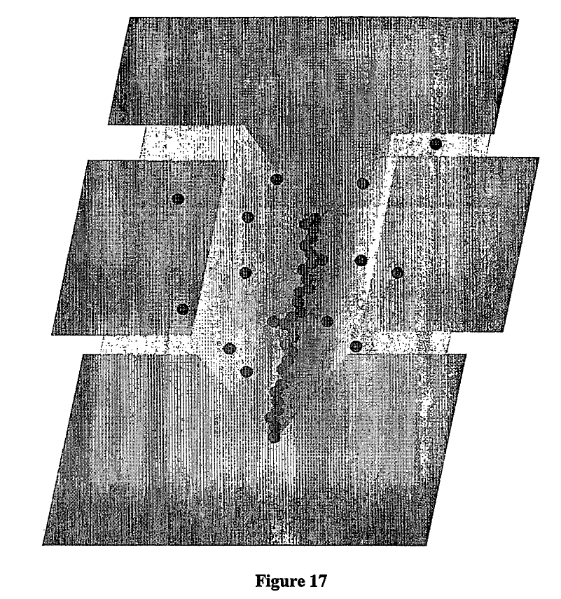

The abovementioned list of possible applications may be embodied in a number of different ways, specific examples of these include the following (which are included within the scope of the invention):
i) A device in which V-grooves or other surface templated structures are defined in the surface of a suitable semiconductor material such as silicon or GaAs (i.e. a material which has appropriately different etch rates for different crystallographic planes) in order to control the final position of deposited nanoparticles, thus achieving a structure which includes a chain of clusters, or a network of clusters with a narrowest point that includes a single cluster or chain of clusters, or a wire-like structure whose diameter is substantially greater than that of the individual clusters deposited. Nanoclusters can migrate across a substrate and then line up at certain surface features[15,16], thus generating structures resembling nano-scale wires. Nano-scale surface texturing techniques (for example v-grooves etched into the surface of a Si wafer [44], pyramidal depressions or other surface features) will force clusters to assemble into nano-scale wires. Migration of mobile clusters on the surfaces of the v-groove should cause the formation of a chain or wire at the apex. Similarly, sliding of the clusters under the influence of the kinetic energy with which they are incident on the surface will cause movement towards the apex of a V-groove, and changes of the angle of deposition can be used to influence the amount of sliding. The concept is that expensive and slow nanolithography processes (the ‘top-down’ approach) will be used only to make relatively large and simple electrical contacts to the device, and possibly for the formation of the v-grooves. Self assembly of nanoscale particles (the ‘bottom-up’ approach) is then used to fabricate the nanoscale features. At the heart of the devices is the combination of ‘top down’ and ‘bottom up’ approaches to nanotechnology. As discussed previously, the method of this invention is not limited to wires of nanoscale dimensions, but may also prove useful for the formation of larger wires up to 100 um in width.
ii) A device as described in i) in which electrical contacts are defined so as to contact the cluster chain achieved using the templating technique. These devices and each of the devices described below may work in an AC or DC or pulsed mode.
iii) A larger device consisting of two or more of the devices described in i) and ii), either to define a better or differently functioning device, or by inclusion of a percolating device of the form described in [30] to allow control of the wire thickness.
iv) A device as described in i) or ii) where by monitoring the onset of conduction the formation of a wire like structure is observed.
v) A device as described in i) or ii) in which two or more contacts of equal or unequal separation are arranged in any pattern and where the contacts are of any shape including interdigitated, regular or irregular arrangements.
vi) FIG. 13 shows a device in which V-grooves running between contacts 1 and 3 (largely obscured by the clusters which accumulate in the valleys) cause contacts 1 and 3 to act as ohmic contacts to the cluster wires formed, and cause contacts 2 and 4 to be isolated from the wires so that they can act as gates (the crests of the V-grooves are represented by dashed lines and the valleys of the V-grooves by solid lines). The device is then similar to a field effect transistor (FET): the voltage applied to the gate attracts (repels) electrons from the connected path thereby increasing (decreasing) the conductivity of the chain of clusters, and turning the device on (or off).
vii) A further preferred embodiment of the device described in vi) includes only a single V-groove, and thus creates a single nanowire (FIG. 17).
viii) Further preferred embodiments of the devices described in vi) and vii) include such devices with an contact arrangement which allows ohmic contact to the nanowire formed in the bottom of the V-groove or inverted pyramid. Many such configurations can be envisaged, including single metallic contacts at each end of the V-groove (as in FIG. 17), interdigitated contacts perpendicular to the V-groove, as well as metallic contacts at each corner of an inverted pyramid (See FIG. 19).
ix) In FIG. 17, if the contacts on the top surface, away from the V-groove, are made of a material that does not form an ohmic (i.e. conducting contact) to the network, those contacts will be predetermined as gates, and the contacts that meet the apex of the V-groove as source and drain. In this example the side contacts might be made from a material which is known to form a Schottky contact to the cluster network, or from a material like aluminium or silicon which has been oxidised to form a tunnel barrier. In this example, the function of the contact pads can be determined prior to deposition.
x) It is possible to create an oxide or other insulating layer on the substrate and then use lithographic techniques so as to define an area such that only clusters landing in that area participate substantially in the cluster network formed. Only clusters landing in the window (region not coated in oxide) can connect to the source and drain contacts. In this way devices may be isolated from one another and the function of the contacts can be pre-determined. In FIG. 15 the insulating coating covers the gate contact and isolates it from the cluster film. Isolation of a contact could also be achieved by making it of a material (such as aluminium) which oxidizes naturally. This technique can be used to pre-determine the function of one or more contacts to be gates or ohmic contacts. FIG. 15 shows source 1 and drain 2 contacts together with a gate contact 3. The contacts have been coated with an insulating layer 4 which ensures that the gate contact 3 is isolated from the cluster assembled wire running between contacts 1 and 2, which are exposed to the deposited clusters due to the hole in the insulating layer 4, thus achieving a transistor structure
xi) Any of the devices described above which are covered entirely or partially by an oxide or other insulating layer and incorporating a top gate to control the flow of electrons through the cluster assembled structure, thereby achieving a field effect transistor or other amplifying or switching device, as shown in FIG. 18.
xii) Any of the devices described above which are fabricated on top of an insulating layer such as SiOx or SiN, which is grown on top of the template either in order to provide electrical isolation or to change the diffusive or sliding properties of the clusters on the surface on which they are deposited.
xiii) Any of the devices described above which are fabricated on top of an insulating layer which itself is on top of a conducting layer that can act as a gate, which can control the flow of electrons through the cluster assembled structure, thereby achieving a field effect transistor or other amplifying or switching device.
xiv) Any of the devices described above in which the angle of impact of the clusters on the surface of part (or parts) of the sample is chosen or controlled so as to affect the probability of a cluster sliding, bouncing or sticking to part (or parts) of the sample. This can be done by controlling either the angle of incidence relative to the entire substrate or by the angle of any template facets on the substrate.
xv) Any of the devices described above in which the kinetic energy of the clusters is controlled so as to affect the probability of a cluster sliding, bouncing or sticking to part or parts of the sample.
xvi) Any of the devices described above in which switching or amplifying based on spin transport is achieved, thereby producing a spin valve transistor.
xvii) The devices may be fabricated with bismuth clusters, or equally well from any type of nanoparticle that can be formed using any one of a large number of nanoparticle producing techniques, or from any element or alloy. Bismuth clusters are particularly interesting because of the low carrier concentration and long mean free paths for electrons in the bulk material. Other obvious candidates for useful devices include silicon, gold, silver, and platinum nanoparticles. The devices could also be formed from alloy nanoparticles such as GaAs and CdSe. The nanoparticles are formed from any of the chemical elements, or any alloy of those elements, whether they be super-conducting, semi-conducting, semi-metallic or metallic in their bulk (macroscopic) form at room temperature. The nanoparticles may be formed from a conducting polymer or inorganic or organic chemical species which is electrically conducting. Similarly either or both of the contacts and/or the nanoparticles may be ferromagnetic, ferromagnetic or anti-ferromagnetic. Two or more types of nanoparticle may be used, either deposited sequentially or together, for example, semiconductor and metal particles together or ferromagnetic and non-magnetic particles together. Devices with magnetic components may yield ‘spintronic’ behaviour i.e. behaviour resulting from spin-transport. Spin-dependant electron transport across sharp domain walls within the wire [43] or between the wire and contacts can yield large magneto-resistances which may allow commercial applications in magnetic field sensors such as readheads in hard drives.
xviii) For all devices described herein, the temperature of the substrate can be controlled during the deposition process in order to control the migration of particles, fusion of particles or for any other reason. In general, smooth surfaces and high substrate temperatures will promote migration of particles, while rough surfaces and low substrate temperatures will inhibit migration. The fusion and migration of nanoparticles is material dependent.
xix) Any of the devices described above in which a voltage is applied between the contacts during deposition such that a flowing current modifies the connectivity of the particles, the conductivity of the device, or the film morphology. Such an applied voltage may allow a conducting path to be formed between the contacts at surface coverages where no connection would usually exist (see FIG. 32 in Ref [30] which shows a dramatic onset of conduction under applied bias), or conversely, to cause the disruption of a previously existing conducting path. A resistor, diode, or other circuit element connected in series or in parallel with the device can be used to regulate the current flowing so as to control the modification of the films properties.
xx) Any of the devices described above in which the film is buried in an oxide or other non-metallic or semi-conducting film to protect it and/or to enhance its properties (see for example FIG. 18), for example by changing the dielectric constant of the device. This capping layer may be doped by ion implantation or otherwise by deposition of dopants in order to enhance, control or determine the conductivity of the device.
xxi) Any of the devices described above in which the film has been annealed either to achieve coalescence of the deposited particles or for any other reason.
xxii) Any of the devices described above in which the assembly of the nanoparticles is influenced by a resist or other organic compound, whether it be exposed, developed washed away either before or after the deposition or aggregation process.
xxiii) Any of the devices described above in which the assembly of the nanoparticles is controlled or otherwise influenced by illumination by a light source or laser beam whether uniform, focussed, unfocussed or in the form of an interference pattern.
xxiv) Any of the devices described above in which the particles are deposited from a liquid, including the case where the particles are coated in an organic material or ligand.
xxv) A device which has several contacts or ports and which relies on ballistic or non ballistic electron transport through the nanoparticles and which relies on the effect of a magnetic field to channel the electrons into an output port which was not the original output port in a zero magnetic field, or which relies on any magnetic focussing effect.
xxvi) Any of the devices described above which are formed by deposition of size selected clusters or, alternatively, which are formed by deposition of particles that are not size selected.
xxvii) Any of the devices described above which are formed by deposition of atomic vapour, or small clusters, and which results in nanoparticles, clusters, filaments or other structures that are larger than the particles that were deposited
xxviii) Any cluster assembled device fabricated substantially as described in any of the claims above, but which is fabricated without contacts. For example, and array of uncontacted template assembled wires could be used as a wire-grid polariser.
   D. Experimental

The following discloses our preferred experimental set up along with specific examples.

a) Lithography

Standard optical and electron beam lithography has been used to define V-grooves on silicon wafers, or silicon wafers coated with either SiOx or SiN and also to define NiCr and Au contacts on the sample surface in such a way that they either intersect or do not intersect the V-groove. A commercial silicon wafer with or without SiOx or SiN insulating layers is used as the substrate.

a) i) V-Groove Formation

The following deals with the formation of a V-groove surface template on silicon, but similar approaches can be used to form other structures on other substrates.

Sample processing begins with dicing a silicon dioxide or silicon nitride coated (layer thickness typically 100 nm) silicon wafer into 8×8 mm substrates. In order to accurately locate the orientation of the <111> plane, the nitride or oxide layer is initially dry etched through a photoresist mask to form radial slots separated by 2°. These slots are translated into V-grooves in the underlying silicon using 40% wt KOH solution. Once completed, angular alignment of the device V-groove arrays to the test slots (selecting those with the neatest etched profile) is performed through a further photolithographic and dry-etch stage. The V-groove array is formed using the same KOH solution. Approximately 5 um wide silicon V-grooves are produced in silicon with an etch time of approximately 5 minutes using 40% by weight KOH solution which is ultrasonically agitated and heated to 70 degrees centigrade.

Examples of V-grooves and related structures formed in the aforementioned way and imaged using atomic force microscopy are shown in FIGS. 16, 17 and 19. FIG. 16 is an atomic force micrograph of a V-groove etched into silicon using KOH. The V-groove is approximately 5 microns across and was formed using optical lithography. One of the attractions of the technique is that it allows features to be readily scaled down in size, using electron beam lithography.

The specific cluster/substrate pair which is being used determines whether or not the surface of the V-groove needs to be coated with an insulating layer in order to provide insulation between the cluster assembled wire and the substrate. For some cluster/substrate combinations a Schottky contact will be formed, enabling limited isolation of the wire from the substrate. In some cases the native oxide layer on the substrate will provide sufficient isolation. If required, passivation of the V-grooves may be carried out in two ways. At present, the preferred method is to thermally oxidise the entire substrate immediately after forming the V-groove arrays. Oxidation is performed in an oxygen rich dry furnace at 1050 degrees centigrade. An oxidation period of one hour produces a 120 nm thick film of silicon dioxide. The alternative passivation method relies on sputter coated silicon nitride.

a) i) Contact Formation

In most embodiments of the invention contacts will be formed (there may be instances when they are not included however, as discussed below). When included, the contacts are preferably formed using either optical or combined electron-beam/optical lithography stages, but other methods of formation could be used as envisaged by one skilled in the art. An initial evaporation and lift-off using an optical photoresist pattern leaves device fingers (>1 μm width) and contacts extending across the main 3×3 mm device area. Device fingers are located over the single or multiple V-grooves with sub-micron tolerance achieved using vernier alignment marks. Electron-beam patterning is used when sub-micron finger/gap widths are required and these features are aligned to pads created in the first optical lithography process. The final evaporation and lift-off allows large scale device contacts to be positioned at the edge of the 8×8 mm chip. FIG. 17 shows a schematic diagram of a preferred embodiment. It shows a schematic illustration of a cluster assembled nanowire created using an AFM image of a V-groove. The top and bottom contacts are aligned with the apex of the V-groove so as to make electrical contact to the cluster assembled nanowire, which results from motion of clusters along the flat faces of the V-groove. The left and right contacts are aligned with the edges of the V-groove so as not to make electrical contact with the cluster assembled nanowire, allowing these contacts to be used as gates. A transistor structure could also be achieved by fabricating a top gate on top of an insulating layer above the wire, as in FIG. 18, in which there is shown a side view of a FET structure fabricated by first deposition of an insulating layer on top of the cluster assembled nanowire followed by lithographic definitions of a gate contact. FIG. 18 shows two contacts 1, 2, on an insulating substrate 6, with cluster chain 3 between the contacts. The insulating layer 5 is illustrated along with the gate contact 4.

In a preferred embodiment, prior to cluster deposition the substrate will be passivated in order to isolate devices from each other. This can be achieved using a patterned sputter coated silicon dioxide layer. Optical lithography followed by dry etching can be employed to open windows in the silicon dioxide directly over the contact finger/V-groove areas. If thermal oxidation was used to passivate the silicon V-grooves, this final dry etch is timed to avoid significant depletion of the base oxide layer.

The sample is now mounted in a purpose made sample holder with all necessary device contacts, as per the procedure for PeCAN devices [30]. In a preferred embodiment, after cluster deposition and whilst in high-vacuum, the devices can be sealed with an electron-beam evaporated or sputtered insulating film (e.g. SiOₓ). This layer can be used to prevent oxidation of the clusters or as an insulating layer prior to fabrication of a top gate through an additional lithography and metal evaporation stage. FIG. 18 shows a schematic diagram of such a device (V-groove not shown).

Finally, we note that TeCAN devices can take advantage of many forms of surface texturing and are not limited to V-grooves. FIG. 19 shows atomic force microscope images at two different resolutions of the bottom of an ‘inverted pyramid’. Inverted pyramids are formed when etching silicon using KOH and a mask or window with circular or square geometry (rather than slots as described above). It is possible to achieve inverted pyramids with very small dimensions and extremely flat walls (as in the lower image in FIG. 19 where the ridges are due to the quality of the AFM image, and are not representative of the flatness of the surface). In a preferred embodiment electron beam lithography is used to define electrical contacts at each of the four corners of the inverted pyramid, thereby allowing 4 terminal measurements of a cluster assembled wire formed along the edges of the facets. Such 4 terminal measurements may be useful for precise conductivity measurements for, for example, magnetic field or chemical sensing applications. Top and/or bottom gates may also be applied to these structures.

As was noted previously, in the preferred embodiment the contacts are formed prior to cluster deposition but formation of contacts after the cluster deposition is also within the scope of the invention. In this case the contacts would need to be aligned with the wires, and so some form of imaging of the wires would be required, before alignment and contacting. Electron beam lithography is a suitable method of achieving this since it allows both imaging of the surface and high resolution definition of contacts.

Furthermore there may be instances where contacts are not used at all. Such instances would include wire grid polarizes, which are essentially an array of wires. This is within the scope of the invention also.

b) Cluster Formation and Deposition

Our preferred apparatus is a modified version of the experimental apparatus described in Ref. [45]. Bismuth clusters are produced in an inert-gas condensation source. In the source chamber, the metal is heated up and evaporated at a temperature of 750-850 degrees Celsius. Argon gas at room temperature mixes with the metal vapour and the clusters nucleate and start to grow. The cluster/gas mixture passes two stages of differential pumping (from ˜1 Torr in the source chamber down to ˜10⁻⁶ Torr in the main chamber) such that most of the gas is extracted. The beam enters the main chamber through a nozzle having a diameter of about 1 mm and an opening angle of about 0.5 degrees. At the sample the diameter of the cluster beam is about 4 mm. In order to determine the intensity of the cluster beam, a quartz crystal deposition rate monitor is used. The samples are mounted on a movable rod and are positioned in front of the quartz deposition rate monitor during deposition.

Note that the specific range of source parameters appears not to be critical: clusters can be produced over a wide range of pressures (0.01 torr to 100 torr) and evaporation temperatures and deposited at almost any pressure from 1 torr to 10⁻¹² torr. Any inert gas, or mixture of inert gases, can be used to cause aggregation, and any material that can be evaporated may be used to form clusters. The cluster size is determined by the interplay of gas pressure, gas type, metal evaporation temperature and nozzle sizes used to connect the different chambers of decreasing pressure. All of these factors could be altered in order to alter the particular form of the wire/nanoparticles produced.

Ionised clusters and/or a mass selection system may be used in a deposition system, for example incorporating a mass filter of the design of Ref [46] and cluster ionisation by a standard electron beam technique. We have constructed a new Ultra High Vacuum cluster deposition system which incorporates these features as well as the added advantages of lower ultimate pressures and a cluster source employing a magnetron sputter head. Si cluster assembled wires produced using this technique are discussed below, otherwise all results discussed here were obtained with the original high vacuum system.

A feature of all our deposition systems (that is not typically incorporated into most vacuum deposition systems, such as the design of Ref. 27) is the use of electrical feedthroughs into the deposition chamber, to allow electrical measurements to be performed on devices during deposition. Such feedthroughs are standard items supplied by most companies dealing in vacuum equipment.

(c) Measurement during Deposition

The core of the measurement circuit was a Keithley 6514 Electrometer with a resolution of 10⁻¹⁵ A. Therefore, the limiting factor for the current resolution is the noise in the system. A current independent voltage source with a fixed output voltage in the range 5 mV to 5V supplied the required stable potential.

The measurement of the current flowing in the device during deposition is important to the realisation of several of the device designs.

(d) Experimental Realisation of V-Groove Assembled Wires

This section describes the experimental realisation of nanowires deposited at the base of silicon V-grooves and assembled from metallic clusters. These clusters are formed in a high vacuum cluster generation system. The metallic material from which the clusters are formed is contained in a crucible within the source chamber. The temperature of the crucible is monitored and controlled via a thermocouple mounted in the base of the crucible. Once the temperature of the crucible is raised beyond the melting point of the host metal, clusters are grown from the metallic vapour within the source chamber. The growth process relies on the presence of an inert gas and in the case of the bismuth, antimony and silver clusters described here argon and/or helium is used. The inert gas is fed through a flow controller and then directly into the source chamber in close proximity to the crucible. A source exit nozzle generates an inert gas/cluster output beam which is directed through nozzles in two differential pumping stages and finally into a high vacuum chamber. The high vacuum chamber houses a sample arm/shutter mechanism and a deposition rate monitor.

Before the pumping sequence begins, substrates are introduced on the sample arm through a port in the high vacuum chamber. Up to eight substrates can be mounted on the sample arm whilst the system is vented. This multi-sample capability enables rapid experimental characterisation of (cluster behaviour on varying substrate materials/topologies with different source conditions.

The rate of deposition of cluster material is monitored via an oscillating crystal film thickness monitor (FTM) mounted behind the sample and inline with the cluster beam. A stable rate is established using the FTM prior to deposition. The substrate holder is then moved in front of the crystal behind a shutter which is opened to begin deposition. The deposition rate is affected by the inert gas flow rate and the temperature of the molten metallic source. The deposition rate for a given gas flow rate is thus adjusted via the temperature of the source.

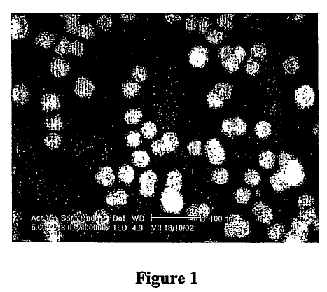

The cluster size is also affected by the source pressure, crucible temperature and gas mix. Field emission SEM images (FIG. 1) and AFM images (not shown) have been used to estimate the sizes of clusters deposited onto various substrates. TEM has been used independently to characterise the cluster size distribution in the beam. In this work, the diameter of the clusters deposited were all between 5 and 100 nm in the case of Bi and 5 and 120 nm in the case of Sb. We note that as discussed below, the sizes of structures in the apex of V-grooves and on plateaus between grooves can be different due to aggregation of the particles.

The cluster beam has a Gaussian flux characteristic with average diameter of 3-5 mm (depending on the chosen source and first differential pumping stage nozzle diameters). This Gaussian profile can be exploited to provide information relating to different deposited film thicknesses on an individual substrate. For example, the deposition time can be selected to produce less than a monolayer of cluster coverage at the edge of the circular beam spot and multi-layer coverage at its centre. This is a feature of the deposition process which allows rapid investigation and characterisation of the deposited clusters as well as their motion on differing substrate surfaces, because a single sample allows investigations for a large range of surface coverages.

The following paragraphs categorise the main types of deposition experiment Initially the cluster deposition apparatus was used to investigate aggregated bismuth cluster nanowires on (unpassivated) silicon V-grooved substrates. Enhanced movement of Bi clusters is seen on silicon dioxide (passivated) V-grooved substrates. Experiments involving antimony cluster nanowires on silicon and silicon dioxide have also been performed, leading to experiments with Ag and Si clusters on passivated and non-passivated silicon substrates.

In the following examples we have illustrated the invention with Bi, Sb, Ag and Si clusters. These are illustrative and are not a restriction on the identity of a cluster, and thus wire, formed in accordance with the invention.

Bismuth Clusters

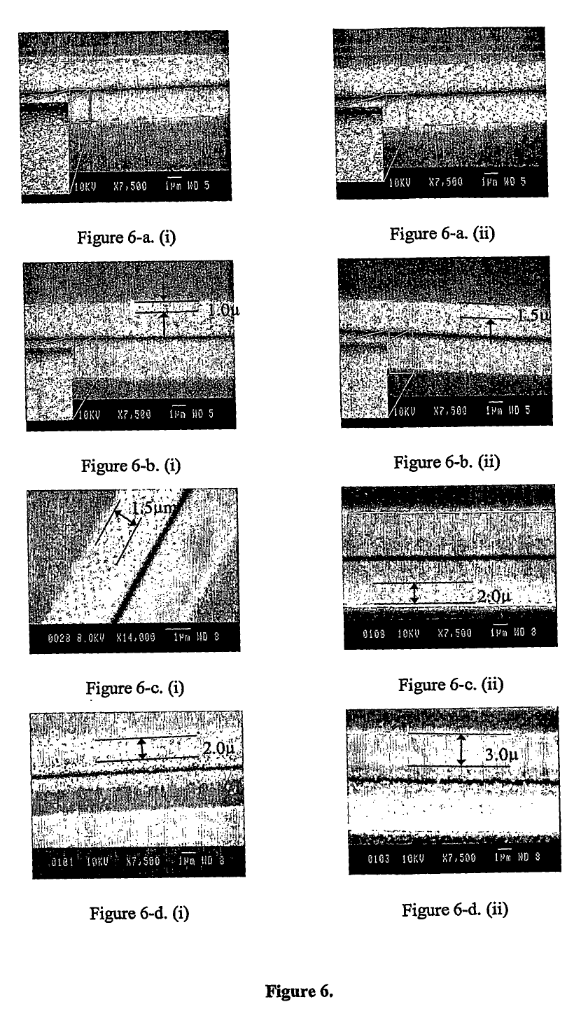

FIG. 6 (a) (i) shows a V-grooved silicon substrate with a bismuth clusters deposited using an argon flow rate of 30 sccm. Whilst some cluster motion towards the apex of each V-groove is evident in this sample, the effect is not pronounced enough to produce true nanowires. FIG. 6 also shows substrates that have been coated with bismuth clusters with higher argon flow rates, resulting in narrower wires in the apex and far cleaner upper V-groove walls than those seen in FIG. 6 (a) (i).

This comparison serves to illustrate the mechanism by which bismuth nanowires are formed. The argon gas stream (introduced to the source chamber to facilitate aggregation of the metallic vapour) gives the clusters sufficient momentum to drive them to the base of the V-walls. As the flow rate is increased, the average cluster momentum is increased, leading to a lower probability that clusters stick to the substrate when they land. The V-groove exploits the tendency of the clusters to bounce or slide and directs them to the narrow apex where they line up/aggregate to form wire-like structures.

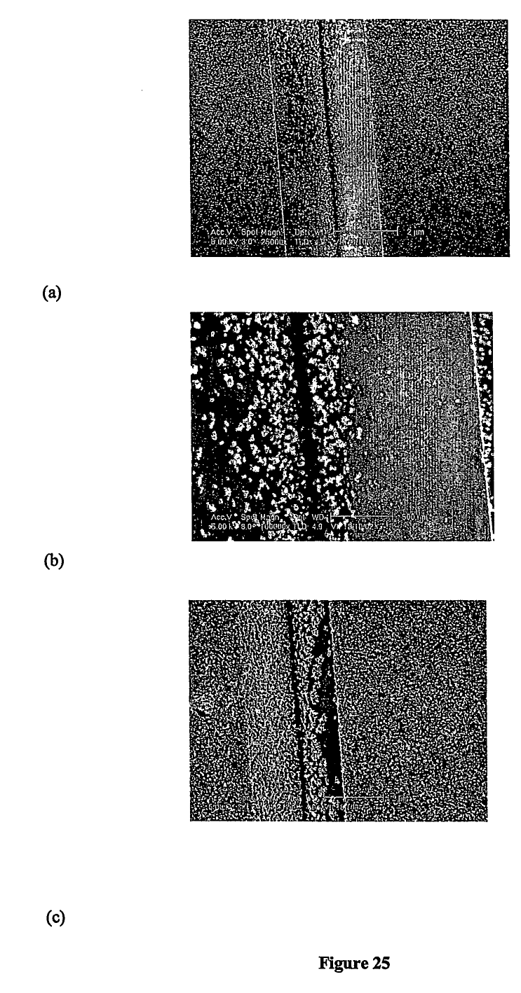

FIG. 25 (a) shows a region of a Si V-grooved substrate deposited using an Ar flow rate of 90 sccm where there is a rapid change in the deposited film thickness due to the differing deposition rates at different points in the beam profile. It illustrates the ability to gain information on different coverages on a single substrate. This figure also shows the increased aggregation of clusters into larger particles which sometimes occurs at the base of the V-grooves. Measurement using FE-SEM of average cluster size across the V-grooved substrate indicates that cluster size is higher in the base of the V-grooves than on the plateaus surrounding them. This effect is attributed to the increased cluster-cluster collisions occurring at the base of the V-grooves. Samples created with short deposition times and high deposition rates show greater aggregation than those created with longer deposition times and lower cluster flux.

The key effect demonstrated in FIG. 25 (a) (as well as in other figures contained herein) is that the thickness of the wire-like structure formed in a particular section of V-groove depends on how close that section is to the centre of the beam spot. The closer to the centre, the higher the deposition rate and total film thickness achieved at that spot. When larger numbers of clusters are deposited in a given area the final wire-like structure is wider i.e. the clusters are ‘backed-up’ further toward the top of the V-groove.

FIG. 25 (a) also shows the effect of changing the angle of impact on the sides of the V-grooves. In this case the V-grooves are not symmetrical due to some misalignment in the silicon wafer slicing process, and the two sides of the V-groove present different angles to the incoming clusters. The side presenting the shallower angle clearly shows less movement of the clusters after arrival; in an area with the same density of particles the wire is thicker and the clean area at the top of the V-groove surface is smaller. FIGS. 25 (b) and (c) show the same effects in more detail, in close up (b) and at higher overall coverages (c).

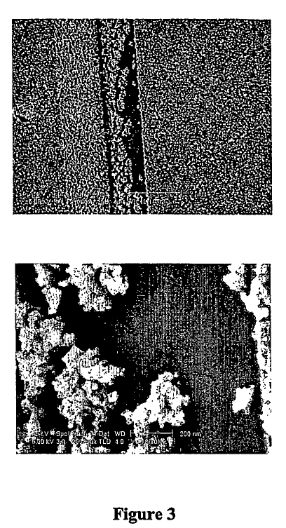

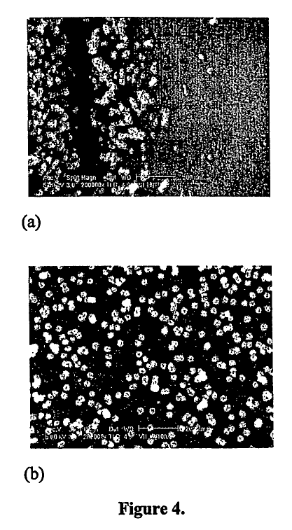

FIG. 3 illustrates enhanced cluster aggregation effects at the apex of a V-groove. This image was obtained using Field Emission SEM analysis and shows a sample coated with bismuth clusters generated with an argon flow rate of 90 sccm. It also demonstrates that under certain conditions, when there is a limited amount of sliding by the first clusters deposited, later clusters to arrive can partially aggregate before finally an avalanche of the large aggregate occurs, presumably when a sufficiently large impact occurs. Images comparing the coverage and size of clusters in a V-groove and on a neighbouring plateau are shown in FIG. 4. Experimental evidence suggests that the degree of cluster aggregation seen at the base of the V-grooves is dependant on the coverage and on the rate of deposition.

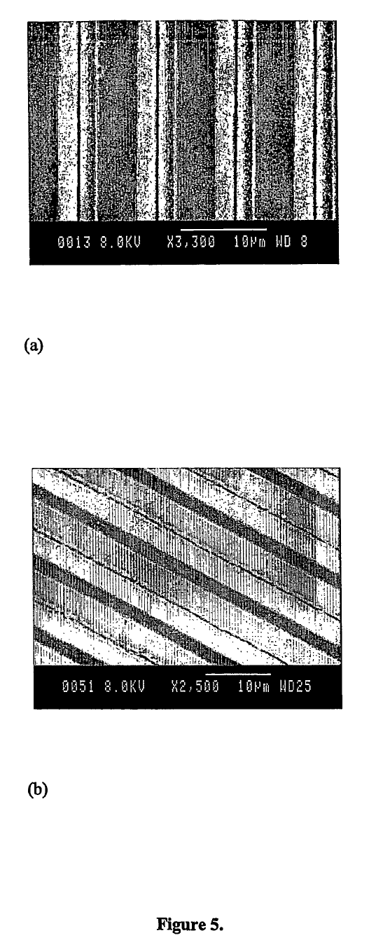

FIG. 5 shows a comparison of bismuth cluster movement on passivated (120 nm thick silicon dioxide) and unpassivated silicon. The argon flow rates and crucible temperatures were identical (within measurable deviations) for these samples. The V-groove walls are noticeably cleaner on the passivated sample indicating lower cluster-surface friction and enhanced motion towards the apex of the V-groove. This characteristic is also evident when comparing passivated and unpassivated samples with lower identical argon flow rates.

FIG. 6 illustrates how the flow rate of the argon is used to control the width of the bismuth nanowires on silicon dioxide. Both the width of the wire and the cluster density at the top of the V-walls decrease as the flow rate of the argon is increased. The lower cluster occupancy at the top of the V-groove walls is particularly apparent on the samples coated with higher inert gas flow rates (yielding higher momentum clusters). FIG. 6 illustrates the lack of cluster material seen at the top of V-groove walls for a sample with an argon flow rate of 180 sccm. FIG. 6 (b) also shows that no cluster accumulation has occurred at the defects on the wall of the V-groove. Therefore no contact has been made between the wire at the apex and the neighbouring plateau. The momentum driven assembly method reliably produces nanowires that are isolated from the silicon plateaus between them. Furthermore due to the low total coverage required to produce a nanowire, connection is made along the apex of the V-groove before connection is established across the flat part of the substrate between the groove.

FIG. 6—shows ((i)—left side) unpassivated and ((ii)—right side) passivated V-grooved Si substrates on which Bi clusters were deposited. Deposition process times were selected to give similar coverages on all the samples illustrated and the argon flow rates ((a) 30, (b) 60, (c) 90 and (d) 180 sccm) were chosen in order to demonstrate the accumulation effects which are a reproducible characteristic of the cluster-on-V-groove experiment. FIG. 6-a shows the low-flow case (argon flow rate was 30 sccm) where the cluster film appears uniform. FIG. 6-b shows a similar pair of V-grooved samples on which clusters have been deposited using an argon flow rate of 60 sccm. The cluster films on both the Si and SiO₂ samples feature areas (of width 1 μm and 1.5 μm respectively) near the tops of the V-grooves which have noticeably lower densities of clusters. A cluster free area is also seen in FIG. 6-c where the widths are now 1.5 μm and 2 μm for the Si and SiO₂ V-grooves respectively. The widths of the cluster free areas in FIG. 6-d (deposition with argon flow 180 sccm) are 2 μm and 3 μm for the Si and SiO₂ V-grooves respectively. (All quoted widths of the cluster free areas refer to the average distance (parallel to the slope) between a continuous cluster film and the top of the V-groove).

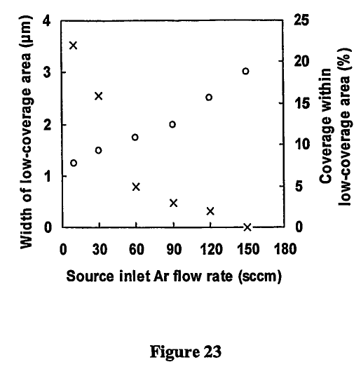

There is a clear correlation between the width of the cluster free area and the source argon flow: the average cluster momentum is increased as the gas velocity through the exit nozzle of the source is increased and this in turn leads to an increase in the average distance that the clusters slide on the sloping walls of each V-groove (a similar effect is shown for Sb clusters in FIG. 23). When argon flows exceed ˜150 sccm, the walls of 4-7 μm wide SiO₂ V-grooves typically have zero cluster occupancy (even if obvious defects exist on the V-groove walls) and there is a well defined cluster assembled wire at the apex of the groove (FIG. 6-d). The effect is appreciable, although less dramatic, for unpassivated samples.

The measured size of the Bi clusters at the apex of V-grooves was found to be dependant on the cluster coverage and the rate of deposition. Field emission SEM images of clusters in V-grooves at the edge of the cluster beam spot (low coverage) were compared with those taken at the centre of the beam spot (high coverage) and it was found that the average cluster size was largest in the mid-beam areas where the total number of clusters deposited was greatest. This suggests that coalescence is occurring at the apex of the V-grooves. Our further experiments indicate that cluster coalescence and therefore average cluster/wire diameter can be reduced by reducing the deposition rate.

Antimony Clusters

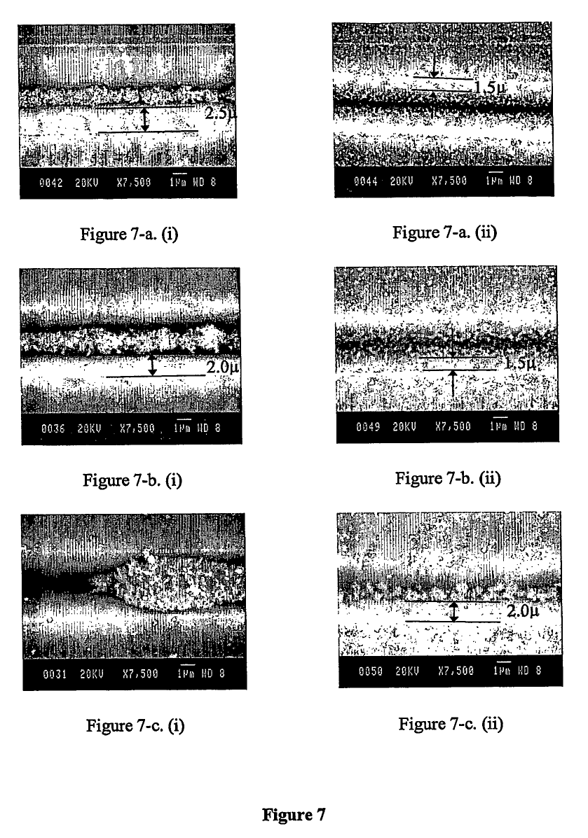

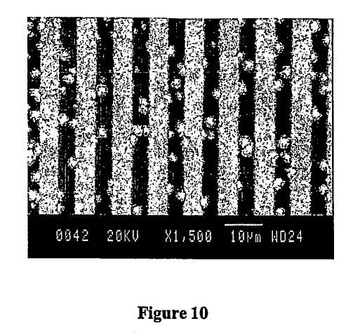

The experiments carried out using Bi clusters were repeated with Sb clusters. FIG. 7 illustrates Sb cluster assembly in Si and SiO₂ V-grooves. When comparing the images of clusters deposited on Si V-grooved substrates in FIG. 7 with those in FIG. 6, it is apparent that the Sb clusters have not assembled in the same way as the Bi clusters. Si samples on which Sb clusters were deposited (FIG. 7-a(i), b(i), c(i)) displayed extremely high contrast in surface coverage: significant build-up of clusters occurred in the apexes of V-grooves whilst the neighbouring plateaus displayed almost zero coverage. Using an argon flow rate of 30 sccm, it was possible to completely fill a Si V-groove with clusters without significant occupation of the neighbouring Si plateaus (FIG. 10). Extremely low cluster coverages seen on the Si plateaus were attributed to clusters bouncing from Si substrate surfaces perpendicular to the cluster beam. At argon flow rates exceeding 50 sccm, wires forming at the apexes of the unpassivated V-grooves often contained breaks and furthermore the wires produced using flow rates above 30 sccm were not more compact than those produced at 30 sccm (FIG. 7-a(i) and FIG. 7-b(i)). FIG. 7-c(i) shows an isolated cluster aggregate formed on a Si V-groove with a source argon flow rate of 90 sccm. Using this flow rate it was impossible to produce wires of any significant length that were narrower than the V-grooves themselves.

By contrast the behaviour of Sb clusters on SiO₂ (FIG. 7 a (ii), b (ii), c (ii)) showed some similarity with the behaviour of Bi clusters on SiO₂ (FIG. 6 a (ii), b (ii), c (ii)). Voids were clearly discernible at the tops of V-grooves even at modest argon flow rates (FIG. 7a (ii), b (ii)) and as with the Bi case, the width of the cluster free area on the V-groove walls increased as the gas velocity through the exit nozzle of the source was increased (FIG. 7c (ii)).

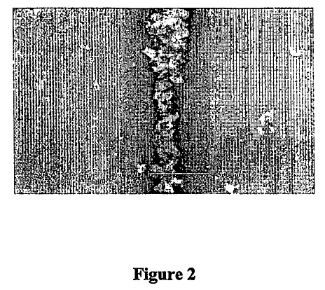

FIG. 2 shows an Sb cluster assembled wire with a minimum width of less than 100 nm ( 1/40th of the width of the V-groove) formed in a 4 μm wide V-groove and at the perimeter of the cluster beam-spot. Irregular shaped and sized (20-100 nm) Sb clusters were found around the perimeter of the cluster beam-spot but as shown in FIG. 2, these clusters assembled at the apexes of V-grooves in identical fashion to the more commonly encountered spherical clusters.

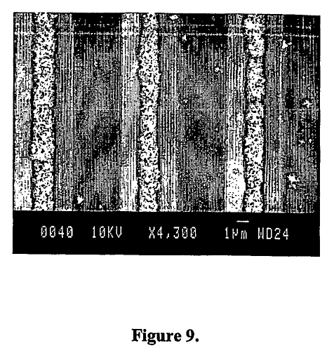

FIG. 9 shows a typical V-grooved silicon substrate on which antimony wires were formed. Cluster accumulation at the apex of the V-grooves is apparent. While there is an absence of clusters on the upper walls of the V-grooves it is also clear that the plateaus between V-grooves remain largely uncoated. It appears that sufficient cluster momentum has been imparted by the argon stream to cause clusters to bounce off the flat surface. This effect can be seen most obviously when deposition is prolonged enough to produce very thick wires which almost completely fill the silicon V-grooves (FIG. 10). Whilst cluster aggregates appear at defects on the plateaus, the cluster occupancy is many times lower on the plateaus than on the neighbouring V-grooves. We believe that a defect on the plateau can act as a ‘soft landing site’ for an impinging cluster, and that the cluster then acts as a ‘soft landing site’ for subsequent clusters.

FE-SEM images of Sb clusters deposited on 4 μm wide V-grooves using different Ar flow-rates have been used to measure the width of the low-coverage region Δ and the coverage (percentage of a monolayer) within these low-coverage regions (FIG. 23). FIG. 23 demonstrates quantitatively how the width of the low-coverage region increases with cluster velocity, and how the coverage within the low-coverage region decreases.

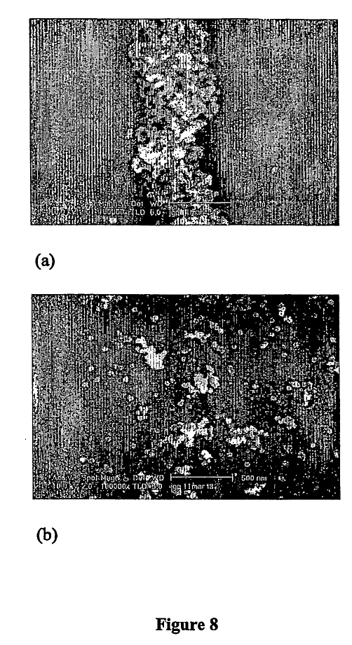

FIG. 8—shows a plateau (a) and neighbouring V-groove (b) on a SiO₂-coated sample after Sb cluster deposition at 180 sccm, at a location where a solid nanowire has just formed in the apex of the V-groove. Coverage on the silicon plateau is less than 40% and no connection across it is feasible.

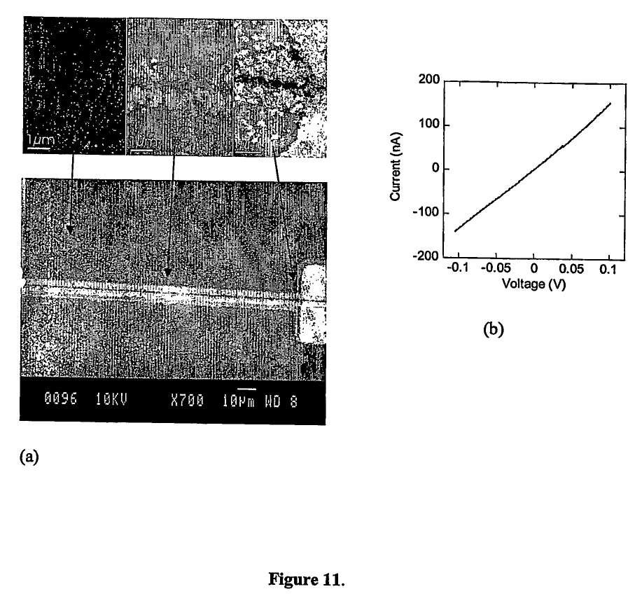

FIG. 11—shows a Sb cluster assembled wire along the apex of a 6 μm wide SiO₂ coated V-groove running between two planar Au contacts. The V-groove method affords high selectivity in forming a conduction path and FIG. 11-(a) demonstrates that even with a V-groove assembled wire of approximately 3 μm width, the coverage on the planar surface was significantly below that required for conduction. The I(V) characteristic taken from this wire is shown in FIG. 11-(b).

Silver Clusters

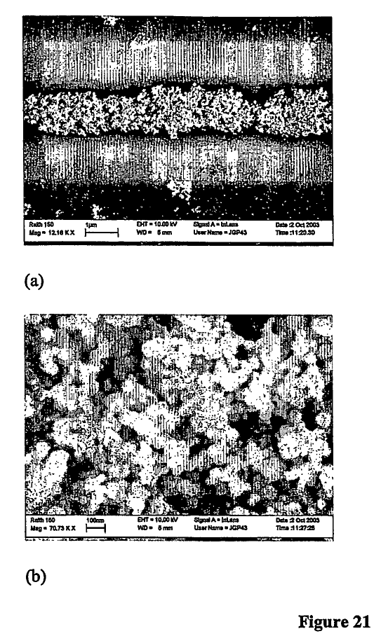

The same techniques used to produce Sb and Bi cluster-assembled wires have been used to produce Ag cluster-assembled wires. Ag clusters are produced in an inert gas aggregation source, but the source is operated at higher temperatures. SEM images of Ag clusters deposited on a SiO₂ passivated V-grooved substrate are shown in FIG. 21. As is the case for similarly deposited Sb clusters, Ag clusters accumulate in the bottom of the V-groove and a near complete absence of clusters is seen near the top of the V-grooves and on the planar surfaces. High magnification images (FIG. 21 bottom) show that the clusters aggregate on the surface with only a limited degree of coalescence.

Silicon Clusters

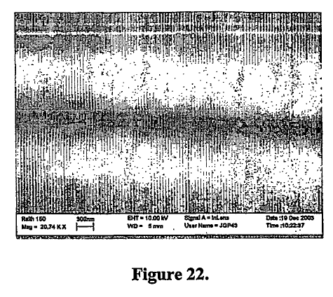

Clusters have also been produced using a source in which a magnetron sputtering unit replaces the crucible arrangement described above. An entirely new cluster deposition system has also been constructed which is UHV compatible, and this will eventually allow deposition to take place at much lower pressures; at present the system is used in a configuration that enables deposition only at pressures comparable to those in the high vacuum system described above. FIG. 22 shows the result of deposition of Si clusters onto a SiOₓ coated V-groove.

FIG. 22 further illustrates the utility of the templating technique described herein. Semiconducting Si clusters have been used to achieve a nanowire with width of approximately 100 nm. A near complete absence of clusters is seen near the top of the V-grooves and on the planar surfaces. Significant coalescence of the aggregated Si clusters at the apex of the V-groove leads to the formation of a continuous Si nanowire with extremely uniform width.

Concluding Remarks

The examples given above demonstrate that each of Bi, Sb, Ag, and Si clusters assemble to form wires and nanowires. While there are some differences in detail, such as the size ranges and flow rates required to achieve wires, the general principle that templates such as V-grooves provide a useful method for cluster assembly remain the same. The invention is not limited to Bi, Sb, Ag and Si clusters. As will be envisaged by those skilled in the art, other suitable clusters could be used. The invention can be applied to any cluster-substrate pair where the cluster is able to migrate on the templated substrate surface.

Conventional photolithography and low resolution masks were used to produce both contacted and uncontacted V-grooves with widths from 2 microns to 10 microns. 1 μm wide V-grooves have been achieved using standard high resolution optical lithography whilst V-grooves with widths down to ˜10 nm can be created using electron-beam defined masks. The ability to scale down will allow compact device designs and close proximity of device contacts and gates.

We note that the width of the V-groove plays an important role in the formation of the wires. The opening at the top of the V acts as a collector area, the width of which determines the total number of clusters (per unit length of V-groove) available for formation of a wire. Clearly, for a given total deposited surface coverage, a large V-groove width collects a large number of clusters (per unit length of V-groove) and hence cause the wire formed to be relatively wide. Narrow V-grooves will cause the formation of relative narrow wires.

Bouncing or Sliding Clusters

FIGS. 5 (b) and 6 (d) (ii) show V-grooves with clear defect lines along the V-groove walls. These defects are due to misalignment between the mask used in lithography and the crystallographic planes of the silicon. FIG. 6 (d) (ii) shows clearly that clusters do not aggregate at these defects and is therefore a strong indicator that bouncing or sliding (rather than simple diffusion) is a key mechanism for the formation of our wires. Note that clusters diffusing on graphite aggregate [16] at (much smaller) atomic surface steps. The low cluster coverages on the SiO₂ plateaus between the V-grooves strongly support the bouncing cluster model. The possibility that the clusters move off the plateaus due to surface diffusion can be discounted due to the large widths (˜8 μm) of the plateaus and their RMS surface roughness (˜5 nm).

Further experimental observations support the bouncing cluster model. Firstly, large quantities of backscattered Sb clusters have been collected on the backside of an aperture placed in front of the sample. Secondly, in separate experiments, the deposition of Sb and Bi clusters between lithographically defined contacts on planar surfaces has been compared. The time taken to form an electrically conducting (percolating) film is ˜3.5 times longer for Sb cluster deposition than for Bi, under otherwise comparable conditions. This indicates that only ˜30% of incident Sb clusters stick to the surface on which they are deposited. This comparison with Bi clusters, which also reach the apex of V-grooves without aggregating at defects, suggests that the Bi clusters are ‘stickier’ i.e they bounce less strongly (perhaps in a motion more equivalent to an energetic sliding) than the Sb clusters.

The existing cluster literature does not seem to provide a framework in which to understand the bouncing phenomenon. A comprehensive review of the different possible outcomes of cluster deposition [47]—which include soft-landing, fragmentation, implantation, and sputtering—recognizes the possibility of reflection from ‘hard’ surfaces but there appear to be no previous simulations or experiments that directly demonstrate this. Considering the large number of studies of fragmentation in the literature, the relatively small size distribution of the clusters and lack of evidence for fragmentation (FIGS. 2, 6 and 7) is very surprising. The large (˜40 nm) clusters produced for these experiments, with high total kinetic energies (>10 keV) but very low energies per atom (<0.01 eV/atom), are in a distinctly different regime to those considered in previous simulations and experiments.

Simulational studies of thin film formation as a result of cluster deposition [48] have shown that different film morphologies are expected for different incident energies, but bouncing of clusters was not observed. Interestingly, [48] shows that in the soft landing regime (<1 eV/atom) [47], films of small clusters should be relatively lightly packed, with minimal coalescence, i.e. with open structures similar to that shown in FIG. 1b.

The bouncing (nanoscale) cluster phenomenon does however appear to have many similarities with that of bouncing (microscale) liquid droplets, as discussed in more detail below.

### EXAMPLES

The invention is further illustrated by the following examples:

1. Lithography Processes

Combinations of optical and Electron Beam Lithography and their use in the formation of surface features and contacts have been described in a previous patent application [30] and are hereby incorporated by reference.

2. Results of Cluster Deposition Experiments

Deposition of bismuth clusters onto plain SiN surfaces (or such surfaces with predefined electrical contacts) and the imaging of such cluster films using atomic force, optical and field emission scanning electron microscopy (FE-SEM) has been described in a previous patent application [30] and are hereby incorporated by reference. The FE-SEM images in that previous work show that the clusters do not diffuse and coalesce significantly on SiN: there is a limited amount of coalescence—the clusters merge very slightly into their neighbours—but in general the particles are still distinguishable. In the present work (see images in FIGS. 1-12) there is a greater degree of coalescence of particles in the apex of V-grooves, and, in addition to devices comprising single wire-like chains, the construction of larger diameter particles and wires with diameters comprising many particles is a significant aspect of the invention.

3. Electrical Characterisation of Cluster Films

Electrical measurements on untemplated cluster films both during and after deposition have been described previously [30] and are hereby incorporated by reference. It is expected that similar results will be obtained for templated cluster devices.

4. Effect of Incident Kinetic Energy on the Detachment of Clusters After Landing

Without wishing to be bound by any particular theory, we make the following observations:

Davies and Rideal (see p 441 in Ref [49]) consider a liquid drop impacting on a solid surface with a certain kinetic energy, and specifically they consider the possibility that the drop will detach itself from the surface after impact. The principle is that the energy of attachment to the surface, which depends mainly on the surface tension of the liquid/air interface and the contact angle to the surface, may be overcome by the kinetic energy of the incoming droplet. In other words the attachment energy is insufficient to bind the energetic droplet to the surface, causing the droplet to ‘bounce’.

If we make the assumptions that
1) bismuth clusters are liquid, or that the effective surface tension of the solid cluster is similar to that of the liquid and that the same principles will apply, and
2) the surface tension applicable is that of bulk bismuth at 270 degrees centigrade (the melting point of bismuth) i.e. γ=390 dynes/cm [50], and
3) the contact angle is ˜90 degrees, and
4) the clusters are incident at normal incidence, and
5) only 50% of the available kinetic energy can be channelled into detaching the cluster, and
6) The velocity of the incoming clusters is similar to that of the inert gas flowing through the nozzles of the source chamber,
   it is then possible to calculate the ratio of the kinetic energy to the detachment energy, as a function of cluster size. If this ratio is greater than 1 (the limit value) the cluster is likely to bounce/detach.

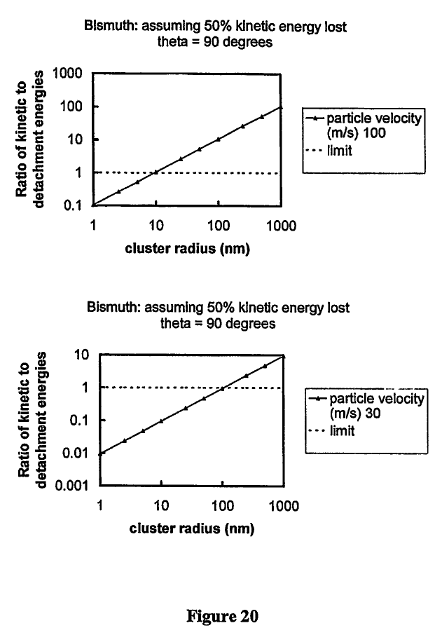

FIG. 20 shows the calculated ratios as a function of cluster size. Clearly, the probability that a cluster will bounce depends dramatically on its size, with larger clusters more likely to bounce, and smaller clusters more likely to stick (and then possibly to migrate). For the realistic velocities chosen, the threshold size is in the range of cluster sizes which is technologically important (i.e. below 100 nm), and this bouncing behaviour may provide an explanation for both the observed movement of clusters toward the apex of a V-groove, and also the absence of clusters from some planar substrate regions on which they would have been expected. As will be apparent to those skilled in the art, the effect of the angle of impact can be taken into account in similar calculations.

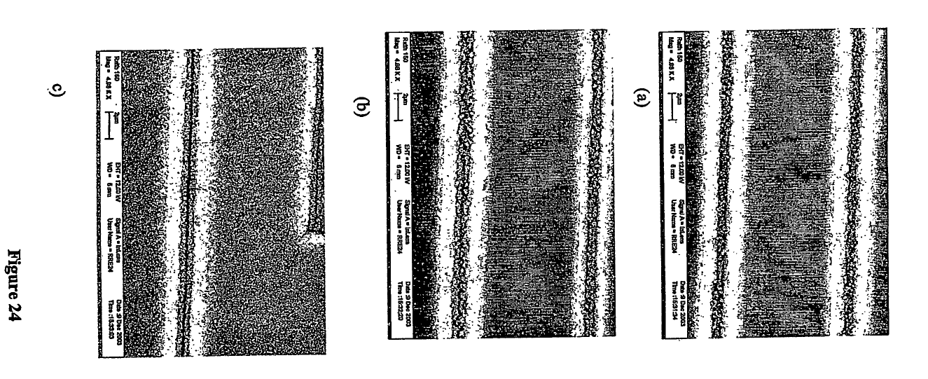

Investigations into the effect of changing the cluster size have been conducted. The Sb clusters shown in FIG. 24 (a), (b) and (c) were deposited with identical Ar flow-rates and therefore with similar velocities, but with different He flows and therefore different cluster sizes (40, 25 and 15 nm respectively). Significant variation is seen in the coverage on the plateaus (<1% to >100%) whilst the V-grooves are comparably filled. This difference in cluster-sticking on the plateaus is attributed to the variation in mass and therefore kinetic energy (K.E.) of the deposited clusters. Larger clusters have higher K.E. and are more likely to be reflected from the silicon dioxide surfaces perpendicular to the cluster beam.

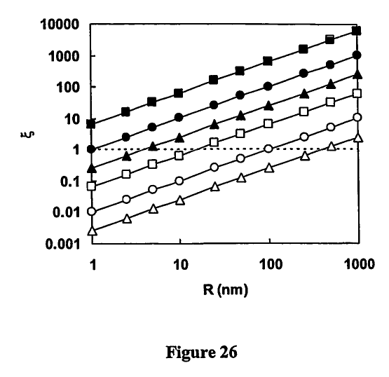

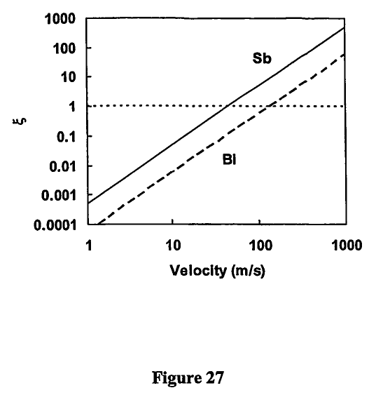

The observed wetting of the surface by both Bi and Sb clusters is evidence of a strong cluster-surface interaction, and suggests that the clusters could be treated as droplets. The known values for the surface tension [51] and cohesive energy [52] of Sb and Bi are very similar, suggesting that the wetting properties of the surface are crucial. Using FE-SEM photographs to estimate the wetting angle (θ) for Sb clusters on SiOₓ (θ=120 degrees), and following [49], FIGS. 26 and 27 show ξ for the range of cluster sizes and velocities relevant to these studies [53]: Sb clusters ˜40 nm in diameter are expected to bounce (ξ>1) for velocities ≧50 m/s, which are certainly exceeded in the present experiments. Similar calculations suggest that because Bi clusters wet the surface significantly more (AFM images allow an estimate θ˜30 degrees) than Sb clusters, the incident kinetic energies need to be ˜10 times greater for Bi clusters to bounce (i.e. for a given size Bi clusters need to travel 3 times faster—see FIG. 27). This predicted behaviour is in at least qualitative agreement with experiments on Bi clusters which appear to be significantly ‘stickier’ than equivalent Sb clusters: Bi clusters deposited at high velocities (Ar flow rate 150 sccm) result in wire morphologies similar to Sb wires formed at low flow rates (see FIG. 1a).

The foregoing describes the invention. Alterations and modifications as will be obvious to those skilled in the art are intended to be incorporated in the scope hereof.
1 S. Tans et al Nature 393, 49 (1998).
2 See P. Collins et al, Science 292, 706 (2001) and refs therein.
3 A. Rochefort et al. Appl. Phys. Lett. 78, 2521 (2001)
4 V. Rodrigues et al, Phys. Rev. Lett. 85 4124 (2000).
5 A Morpurgo et al, Appl. Phys. Lett. 74, 2084 (1999)
6 C. Li et al, Appl. Phys. Lett. 76, 1333 (2000)
7 P. A. Smith et al., Applied Physics Letters 77 (9), 1399 (2000).
8 Z. Zhang et al., Journal of Materials Research 13 (7), 1745 (1998).
9 Y.-T. Cheng et al., Applied Physics Letters 81 (17), 3248 (2002).
10 C. Z. Li et al., Applied Physics Letters 76 (10), 1333 (2000).
11 R. Palmer, “Welcome to Clusterworld”, New Scientist, 22 Feb. 1997.
12 W. Chen et al, Appl. Phys. Lett. 66, 3383 (1995)
13 See, for example, I. M. Goldby et al, Rev. Sci. Inst. 68, 3327 (1997), and refs therein.
14 See for example, D. Klein et al, Appl. Phys. Lett. 68, 2574 (1996); T. Tada et al, Micro. Eng. 35, 293 (1997); T. Tada et al, Appl. Phys. Lett. 70, 2538 (1997); K. Seeger and R. Palmer, Appl. Phys. Lett. 73, 2030 (1998).
15 I. M. Goldby et al, Appl. Phys. Lett. 69, 2819 (1996).
16 G. M. Francis et al, J. Appl. Phys. 73, 2942 (1996).
17 J. Liu et al, Appl. Phys. Lett. 74, 1627 (1999).
18 S. J. Carroll et al, Appl. Phys. Lett. 72, 305 (1998).
19 W. Chen and H. Ahmed, J. Vac. Sci. Technol. B 11, 2519 (1993).
20 M. Hori et al, Appl. Phys. Lett. 73, 3223 (1998).
21 D. Klein et al Appl. Phys. Lett. 68, 2574 (1996).
22 L. Gurevich et al, Appl. Phys. Lett. 76, 384 (2000).
23 J. Park et. al. Nature 417, 722 (2002); W. Liang et. al. Nature 417, 725 (2002).
24 S. Yamamuro et al, J. Phys. Soc. Jpn, 68, 28 (1999).
25 R. Laibowitz et al, Phys Rev. B. 25, 2965 (1982)
26 R. Voss et al, Phys Rev. Left. 49, 1441 (1982).
27 A. Kapitulnik and G. Deutshcer, Phys Rev. Lett. 49, 1444 (1982).
28 P. Jensen et al, Phys Rev. B 47, 5008 (1993).
29 P. Melinon et al, Phys Rev. B 44, 12562 (1991).
30 International Patent Application number PCT/NZ02/00160; NZ Patent Application number 51367, “Nanoscale Electronic Devices and Fabrication Methods”.
31 J. Jorritsma et al., Applied Physics Letters 67 (10), 1489 (1995).
32 J. Jorritsma and J. A. Mydosh, IEEE Transactions on Magnetics 34 (4), 994 (1998).
33 J. Liu et al., Applied Physics Letters, 73 (14), 2030 (1998).
34 F. J. Himpsel et al., Solid State Communications 117 149 (2001).
35 A. J. Parker et al., Applied Physics Letters 74 (19), 2833 (1999).
36 M. P. Zach et al., Science 290, 2120 (2000).
37 F. Favier et al., Science 293, 2227 (2001).
38 M. Batzill et al., Nanotechnology 9, 20 (1998).
39 D. A. Eastham et al., Nanotechnology 13, 51 (2002).
40 L. Bardotti et al., Applied Surface Science 191, 205 (2002).
41 W. de Heer, Rev. Mod. Phys. 65, 611 (1993)
42 I. M. Goldby et al, Rev. Sci. Inst. 68, 3327 (1997).
43 H. Chopra and S. Hua, Phys. Rev. B 66, 020403 (2002).
44 Similar etching techniques are used for a different type of device structure in H. Ishikuro and T. Hiramoto, Jap. J. Appl. Phys. 38, 396 (1999).
45 B. D. Hall, PhD thesis, Ecole Polytechnique Federale de Laussanne, Switzerland (1991).
46 B. von Issendorf and R. Palmer, Rev. Sci. Inst. 70, 4497(1999)
47 W. Harbich, Ch. 4 in Meiwes-Broer K -H (Ed.) 2000 Metal Clusters at Surfaces (Springer: Berlin).
48 Haberland H, Insepov Z and Moseler M 1995 Phys. Rev. B. 51 11061. See also Moseler M, Rattunde O, Nordick J and Haberland H 1998 Comp. Mat. Sci. 10 452
49 J. T. Davies and E. K. Rideal, Interfacial Phenomena, Academic Press, New York, 1961
50 C. Smithells, Metals Reference Book Vol III (4^{Th} Ed), Butterworths, London, 1967.
51 γ(Bi)=378 mN/m, γ(Sb)=367 mN/m, data from Smithells C J 1976 Metals Reference Book, 5^{th} Ed. (Butterworth-Heinemann)
52 Cohesive energies are 2.75 eV/atom for Sb and 2.18 eV/atom for Bi from Kittel C 1996 Introduction to Solid State Physics, 7^{th} Ed. (Wiley: New York) 57
53 Following Ref. 49 it is assumed that Eᵣ/Eᵢ=0.50, where Eᵢ is the incident kinetic energy. The value of Eₐ is largely determined [See Hartley G S and Brunskill R T 1958 in Danielli J F, Pankhurst K G A and Riddiford A C (Eds.) Surface Phenomena in Chemistry and Biology (Pergamon: London) 214] by a multiplicative factor f(θ), where f(120°)=0.055, and f(30°)=0.75.

1-57. (canceled)

58. A method of forming at least a single conducting chain of particles on a substrate comprising or including the steps of:
a. modifying the substrate surface to provide a topographical feature, or identifying a topographical feature on the substrate surface;
b. preparing a plurality of particles,
c. depositing a plurality of particles on the substrate, and
d. forming a conducting chain of particles.

59. A method as claimed in claim 58 wherein the formation of the conducting chain of particles relies upon the migration, sliding, bouncing or other movement of the particles across or on the surface of the substrate which is due, at least in part, to kinetic energy imparted to the particles prior to deposition.

60. A method as claimed in claim 59 comprising the further step of:
forming two or more contacts on the substrate surface
which step may:
precede, follow or be simultaneous with Step a. and the deposition is in the region between the contacts, and the conducting chain of particles is between the contacts, or
follow step d. and the contacts may be so located that the conducting chain of particles is between them, providing electrical conduction between them.

61. A method as claimed in claim 58 wherein the modifying step includes formation of a step, depression or ridge in the substrate surface.

62. A method as claimed in claim 61 wherein the modifying step comprises forming a v-groove having a substantially v-shaped cross-section or inverted pyramid structure running substantially between the contacts.

63. A method as claimed in claim 62 wherein the surface modifying step:
comprises etching and takes advantage of the different etch rates of crystallographic planes in the substrate material, and/or
comprises lithography.

64. A method as claimed in claim 58 wherein the particles are sized between 0.5 nm and 100 microns and provide a chain of width between 0.5 nm and 100 microns.

65. A method as claimed in claim 64 wherein the particles are nanoparticles and are smaller than the size of the v-groove and the chain is many particles in width between 0.5 nm and 100 microns.

66. A method as claimed in claim 58 wherein the particles are composed of two or more atoms, which may or may not be of the same element.

67. A method as claimed in claim 58 wherein there are two contacts which are separated by a distance smaller than 100 microns.

68. A method as claimed in claim 67 wherein the contacts are separated by a distance less than 1000 nm.

69. A method as claimed in claim 58 wherein the single conducting chain of particles forms a wire.

70. A method as claimed in claim 69 wherein the length of the wire is defined by the spacing between the contacts, or the length of the v-groove or other surface modification.

71. A method as claimed in claim 64 wherein the average diameter of the nanoparticles is between 0.5 nm and 1,000 nm.

72. A method as claimed in claim 71 wherein the nanoparticle preparation and deposition steps are performed by inert gas aggregation and the nanoparticles are atomic clusters made up of a plurality of atoms which may or may not be of the same element.

73. A method as claimed in claim 72 wherein the substrate is an insulating material or a semiconducting material.

74. A method as claimed in claim 65 wherein the substrate is formed of a material selected from the group consisting of silicon, silicon nitride, silicon oxide, aluminium oxide, indium tin oxide, germanium, gallium arsenide, another Group III-V semiconductor, quartz, and glass, and the nanoparticles are formed of a material selected from group consisting of bismuth, antimony, aluminium, silicon, platinum, palladium, germanium, silver, gold, copper, iron, nickel, or cobalt clusters.

75. A method as claimed in claim 58 wherein the nature of the chain of particles is controlled by a step selected from the group consisting of:
controlling the angle of incidence of the deposition of clusters onto the substrate so as to affect the density of particles or their ability to slide, stick or bounce, in or on any part or parts of the substrate;
controlling the angle of the topographical feature(s) on the substrate so as to affect the density of particles or their ability to slide, stick or bounce, in or on any part or parts of the substrate;
adjusting or controlling the kinetic energy of the particles to be deposited on the substrate by control of the gas pressures and/or nozzle diameters of an inert gas aggregation source and/or associated vacuum system and/or velocity of gas from the nozzle
controlling the substrate temperature,
controlling the substrate surface smoothness,
controlling of the surface type and/or identity; and
a combination thereof.

76. A method as claimed in claim 58 wherein the step of forming the at least a single conducting chain comprises:
i. monitoring the conduction between the contacts and ceasing deposition at or after the onset of conduction, and/or
ii. using of a deposition rate monitor to achieve the desired wire thickness.

77. A method as claimed in claim 58 which prior to the deposition step comprises a step selected from the group consisting of:
ionizing the particles;
selecting the size of the particles;
accelerating and focussing clusters of particles;
oxidising or otherwise passivating the surface of a v-groove or other template so as to modify the subsequent motion of the incident particles
selecting particle and substrate materials and the particle's kinetic energy so as to cause the particle to bounce off a part of the substrate, thereby preventing the formation of a conducting path in that area of the substrate.
selecting the size of a surface modification so as to control the thickness of the wire formed; and
a combination thereof.

78. A single conducting chain of particles on a substrate prepared substantially according to the method set forth in claim 58 or 59.

79. A method of forming a conducting wire between two contacts on a substrate surface comprising or including the steps of:
a. forming the contacts on the substrate,
b. preparing a plurality of particles,
c. depositing a plurality of particles, on the substrate in the region between the contacts, and
d. achieving a single wire running substantially between the two contacts by modifying the substrate to achieve, or taking advantage of pre-existing topographical features which will cause the particles to form the wire.

80. A method as claimed in claim 79 wherein the particles are sized between 0.5 nm and 100 microns and provide a chain of dimensions between 0.5 nm and 100 microns.

81. A method as claimed in claim 79 wherein the formation of the conducting chain of particles relies upon the migration, sliding, bouncing or other movement of the particles across or on the surface of the substrate which is due, at least in part, to kinetic energy imparted to the particles upon deposition.

82. A method as claimed in claim 79 wherein the nature of the conducting wire is controlled by a step selected from the group consisting of:
controlling the angle of incidence of the deposition of clusters onto the substrate so as to affect the density of particles or their ability to slide, stick or bounce, in or on any part or parts of the substrate;
controlling the angle of the topographical feature(s) on the substrate so as to affect the density of particles or their ability to slide, stick or bounce, in or on any part or parts of the substrate;
adjusting or controlling the kinetic energy of the particles to be deposited on the substrate by control of the gas pressures and/or nozzle diameters of an inert gas aggregation source and/or associated vacuum system and/or velocity of gas from the nozzle;
controlling the substrate temperature,
controlling the substrate surface smoothness,
controlling the surface type and/or identity; and
a combination thereof.

83. A method as claimed in claim 79 wherein the contacts are separated by a distance smaller than 100 nm, and the average diameter of the nanoparticles is between 0.5 nm and 1,000 nm.

84. A method as claimed in claim 83 wherein the nanoparticle preparation and deposition steps are via inert gas aggregation and the nanoparticles are atomic clusters made up of two or more atoms which may or may not be of the same element.

85. A method as claimed in claim 83 wherein the substrate is formed of a material selected from the group consisting of silicon, silicon nitride, silicon oxide, aluminium oxide, indium tin oxide, germanium, gallium arsenide or another Group III-V semiconductor, quartz, and glass, and the nanoparticles are formed of a material selected from the group consisting of bismuth, antimony, aluminium, silicon, platinum, palladium, germanium, silver, gold, copper, iron, nickel, and cobalt clusters.

86. A method as claimed in claim 79 which prior to the deposition step comprises a step selected from the group consisting of:
ionizing the particles;
selecting the size of the particles;
accelerating and focussing clusters of the particles;
oxidizing or otherwise passivating the surface of a v-groove or other template so as to modify the subsequent motion of incident particles;
selecting particle and substrate materials and a particle's kinetic energy so as to cause the particle to bounce off a part of the substrate, thereby preventing the formation of a conducting path in that area of the substrate;
selecting the size of a surface modification so as to control the thickness of the wire formed; and
a combination thereof.

87. A conducting wire between two contacts on a substrate surface prepared substantially according to the method set forth in claim 79 or 86.

88. A method of fabricating a device including or requiring a conduction path between two contacts formed on a substrate, comprising the steps of:
a. preparing a conducting wire or a conducting chain of particles between two contacts on a substrate surface according to a method as described in claim 58 or 79, and
b. incorporating the contacts and wire into the device.

89. A method as claimed in claim 88 wherein the device includes two or more contacts and includes one or more of conducting wires or chains of particles.

90. A method as claimed in claim 88 wherein the device is a nanoscale device, and the wire or chain is a nanowire.

91. A method as claimed in claim 88 wherein the incorporating step comprises a step selected from the group consisting of:
a. forming two primary contacts having the conducting wire between them, and at least a third contact on the substrate which is not electrically connected to the primary contacts and is thereby capable of acting as a gate or other element in an amplifying or switching device, transistor or equivalent;
b. forming two primary contacts having the conducting wire between them, an overlayer or underlayer of an insulating material, and at least a third contact on the distal side of the overlayer or underlayer from the primary contacts, whereby the third contact is capable of acting as a gate or other element in a switching device, transistor or equivalent;
c. protecting the contacts and/or wire by an oxide or other non-metallic or semi-conducting film to protect it and/or enhance its properties;
d. forming a capping layer over the surface of the substrate with contacts and nanowire;
e. annealing the nanoparticles on the surface of the substrate;
f. controlling the position of the nanoparticles by a resist or other organic compound or an oxide or other insulating layer which is applied to the substrate and then processed using lithography and/or etching to define a region or regions where nanoparticles may take part in electrical conduction between the contacts and another region or regions where the nanoparticles will be insulated from the conducting network; and
g. a combination thereof.

92. A method as claimed in claim 91 wherein the device is selected from the group consisting of a transistor, a switching device, a film deposition control device, a magnetic field sensor, a chemical sensor, a light emitting or detecting device, and a temperature sensor.

93. A method as claimed in claim 88 which prior to deposition comprises a step selected from the group consisting of:
ionizing the particles;
selecting the size of the particles;
accelerating and focussing clusters of the particles;
oxidising or otherwise passivating the surface of a v-groove or other template so as to modify the subsequent motion of the incident particles
selecting particle and substrate materials and a particle's kinetic energy so as to cause the particle to bounce off a part of the substrate, thereby preventing the formation of a conducting path in that area of the substrate;
selecting the size of a surface modification so as to control the thickness of the wire formed; and
a combination thereof.

94. A device including a conduction path between two contacts formed on a substrate prepared substantially according to the method of claim 88.

95. A nano- to micro-scale device including a conduction path between two contacts formed on a substrate comprising:
a. at least two contacts on the substrate; and
b. a plurality of particles forming a conducting chain or path of particles between the contacts;
wherein the particles are deposited upon the surface from an inert gas aggregation source, and wherein formation of the conducting chain of particles relies upon the migration, sliding, bouncing or other movement of the particles across or on the surface of the substrate which is due, at least in part, to kinetic energy imparted to the particles prior to deposition.

96. A device as claimed in claim 95 wherein the nature of the conducting chain or path of particles is controlled by performing a step selected from the group consisting of:
controlling the angle of incidence of the deposition of clusters onto the substrate so as to affect the density of particles or their ability to slide, stick or bounce, in or on any part or parts of the substrate;
controlling the angle of the topographical feature(s) on the substrate so as to affect the density of particles or their ability to slide, stick or bounce, in or on any part or parts of the substrate;
adjusting or controlling the kinetic energy of the particles to be deposited on the substrate by control of the gas pressures and/or nozzle diameters of an inert gas aggregation source and/or associated vacuum system an/or velocity of gas from the nozzle;
controlling the substrate temperature;
controlling the substrate surface smoothness;
controlling the surface type and/or identity; and
a combination thereof.

97. A device as claimed in claim 96 wherein the device is a nanoscale device, and the particles are nanoparticles and the contacts are separated by a distance less than 1000 nm.

98. A device as claimed in claim 97 wherein the nanoparticles are composed of two or more atoms, which may or may not be of the same element, may or may not be of uniform size, and the average diameter of the nanoparticles is between 0.5 nm and 1,000 nm.

99. A device as claimed in claim 97 wherein the substrate is formed of a material selected from the group consisting of silicon, silicon nitride, silicon oxide, aluminium oxide, indium tin oxide, germanium, gallium arsenide or another Group III-V semiconductor, quartz, and glass, and the nanoparticles are formed of a material selected from the group consisting of bismuth, antimony, aluminium, silicon, platinum, palladium, germanium, silver, gold, copper, iron, nickel, and cobalt clusters.

100. A device as claimed in claim 95 wherein the at least a single conduction chain has been formed either by:
i. monitoring the conduction between the contacts and ceasing deposition at or after the onset of conduction, and/or
ii. modifying the substrate surface, or taking advantage of pre-existing topographical features, which will cause the nanoparticles to form the nanowire when deposited in the region of the modification or topographical features.

101. A device as claimed in claim 95 which prior to deposition of the particles thereon is subjected to a process selected from the group consisting of:
ionizing the particles;
selecting the size of the particles;
accelerating and focussing of clusters of the particles;
oxidizing or otherwise passivating the surface of a v-groove or other template so as to modify the subsequent motion of the incident particles;
selecting the particle and substrate materials and a particle's kinetic energy so as to cause the particle to bounce off a part of the substrate, thereby preventing the formation of a conducting path in that area of the substrate.
selecting the size of a surface modification so as to control the thickness of the wire formed; and
a combination thereof.
